(19) United States
(12) Patent Application Publication
(10) Pub. No.: US 2024/0130257 A1
(43) Pub. Date: Apr. 18, 2024

(54) SPREADER CONFIGURATION FOR PHASE CHANGE MATERIAL (PCM) SWITCH AND METHODS OF FORMING THE SAME

(71) Applicant: Taiwan Semiconductor Manufacturing Company Limited, Hsinchu (TW)

(72) Inventors: Fu-Hai LI, Tainan (TW); Yi Ching ONG, Hsinchu (TW); Hsin Heng WANG, Hsinchu (TW); Tsung-Hao YEH, Hsinchu (TW); Yu-Wei TING, Taipei (TW); Kuo-Pin CHANG, Zhubei (TW); Hung-Ju LI, Hsinchu (TW); Kuo-Ching HUANG, Hsinchu (TW)

(21) Appl. No.: 18/304,533

(22) Filed: Apr. 21, 2023

Related U.S. Application Data
(60) Provisional application No. 63/415,287, filed on Oct. 12, 2022.

(51) Int. Cl. H10N 70/00; H10N 70/20

(52) U.S. Cl. CPC H10N 70/8613; H10N 70/023; H10N 70/026; H10N 70/231

(57) ABSTRACT

Devices and method for forming a switch including a heater layer including a first heater pad, a second heater pad, and a heater line connecting the first heater pad and the second heater pad, a phase change material (PCM) layer positioned in a same vertical plane as the heater line, and a floating spreader layer including a first portion positioned in the same vertical plane as the heater line and the PCM layer, in which the first portion has a first width that is less than or equal to a distance between proximate sidewalls of the first heater pad and the second heater pad.

### RELATED APPLICATIONS

This application claims priority from U.S. Provisional Application Ser. No. 63/415,287 entitled “Spreader Configuration For Phase Change Material (PCM) Switch And Methods Of Forming The Same,” filed on Oct. 12, 2022, the entire contents of which are incorporated herein by reference for all purposes.

### BACKGROUND

Electronic devices may utilize switches to route a signal along a transmission path. For example, a communication device (e.g., cell phone) may include many antenna elements and multiple radio streams to ensure high data rate wireless communications, whether through cellular or mobile connectivity networks and peripheral devices. The communication device may utilize radio frequency (RF) switches to route an RF signal along a transmission path that may include multiple RF components such as amplifiers, filters, etc. Phase change material (PCM) switches are used for various applications such as radio-frequency (RF) applications. Advantages of PCM switches include their immunity to interference by electromagnetic radiation, relatively fast switching times, and ability to maintain their switching state (i.e., “On” or “Off”) without consuming electrical power.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a perspective view of a switch (e.g., a radio frequency (RF) switch) having a basic configuration, according to some embodiments of the present disclosure.

FIG. 1B is a vertical cross-sectional view (with the x-direction into the page) of a portion of the switch along the vertical plane I-I′ of FIG. 1A, according to some embodiments of the present disclosure.

FIG. 1C is a plan view (e.g., top-down view) of the switch including the floating spreader layer, according to some embodiments of the present disclosure.

FIG. 2A is a vertical cross-sectional view of an intermediate structure including the substrate, according to some embodiments of the present disclosure.

FIG. 2B is a vertical cross-sectional view of an intermediate structure including the floating spreader layer, according to some embodiments of the present disclosure.

FIG. 2C is a vertical cross-sectional view of an intermediate structure including the insulating layer, according to some embodiments of the present disclosure.

FIG. 2D is a vertical cross-sectional view of an intermediate structure including the opening in the insulating layer, according to some embodiments of the present disclosure.

FIG. 2E is a vertical cross-sectional view of an intermediate structure including a layer of heater material, according to some embodiments of the present disclosure.

FIG. 2F is a vertical cross-sectional view of an intermediate structure including the heating portion of the heater layer, according to some embodiments of the present disclosure.

FIG. 2G is a vertical cross-sectional view of an intermediate structure including the thermal dielectric layer and a layer of PCM, according to some embodiments of the present disclosure.

FIG. 2H is a vertical cross-sectional view of an intermediate structure including the PCM layer, according to some embodiments of the present disclosure.

FIG. 2I is a vertical cross-sectional view of an intermediate structure including a layer of bottom spacer material and a layer of upper spacer material, according to some embodiments of the present disclosure.

FIG. 2J is a vertical cross-sectional view of an intermediate structure including a bottom spacer and an upper spacer according to some embodiments of the present disclosure.

FIG. 2K is a vertical cross-sectional view of an intermediate structure including a layer of signal contact material, according to some embodiments of the present disclosure.

FIG. 2L is a vertical cross-sectional view of an intermediate structure including the positive signal contact and the negative signal contact, according to some embodiments of the present disclosure.

FIG. 3 is a vertical cross-sectional view of a switch having a first alternative structure, according to some embodiments of the present disclosure.

FIG. 4 is a top-down view of a second alternate structure including a floating spreader layer according to some embodiments of the present disclosure.

FIG. 5 is a top-down view of a third alternate structure including a floating spreader layer according to some embodiments of the present disclosure.

FIG. 6 is a top-down view of a fourth alternate structure including a floating spreader layer according to some embodiments of the present disclosure.

FIG. 7 is a top-down view of a fifth alternate structure including a floating spreader layer according to some embodiments of the present disclosure.

FIG. 8 is a top-down view of a sixth alternate structure including a floating spreader layer according to some embodiments of the present disclosure.

FIG. 9 is a top-down view of a seventh alternate structure including a floating spreader layer according to some embodiments of the present disclosure.

FIG. 10 illustrates a vertical cross-sectional view of an eighth alternative structure including a bottom floating spreader and a top floating spreader according to some embodiments of the present disclosure.

FIG. 11 illustrates a vertical cross-sectional view of a ninth alternative structure including a top floating spreader according to some embodiments of the present disclosure.

FIG. 12 illustrates a vertical cross-sectional view of a tenth alternative structure including a bottom whole-area spreader and a top floating spreader according to some embodiments of the present disclosure.

FIG. 13 illustrates a vertical cross-sectional view of an eleventh alternative structure including a top whole-area spreader layer and a bottom floating spreader according to some embodiments of the present disclosure.

FIG. 14 illustrates a vertical cross-sectional view of a twelfth alternative structure including a top whole-area spreader layer and a bottom whole-area spreader according to some embodiments of the present disclosure.

FIG. 15 illustrates a vertical cross-sectional view of a thirteenth alternative structure including a floating spreader layer and a copper floating spreader layer according to some embodiments of the present disclosure.

FIG. 16 illustrates a vertical cross-sectional view of a fourteenth alternative structure including a bottom whole-area spreader layer and a copper floating spreader layer according to some embodiments of the present disclosure.

FIG. 17A illustrates a vertical cross-sectional view of an intermediate structure including forming an insulating layer according to some embodiments of the present disclosure.

FIG. 17B is a vertical cross-sectional view of an intermediate structure including an opening in the insulating layer according to some embodiments of the present disclosure.

FIG. 17C is a vertical cross-sectional view of an intermediate structure including an unetched U-shaped floating spreader layer according to some embodiments.

FIGS. 17D-17F are various views of a fifteenth alternative structure after etching unetched U-shaped floating spreader layer to form a U-shaped floating spreader layer according to an embodiment of the present disclosure. FIG. 17D is a top-down perspective view of the fifteenth alternative structure, FIG. 17E is a vertical cross-sectional view along the horizontal plane A-A′ of FIG. 17D, and FIG. 17F is a vertical cross-sectional view along the horizontal plane B-B′ of FIG. 17D according to an embodiment of the present disclosure.

FIGS. 18A and 18B are various views of a sixteenth alternative structure including a reversed U-shaped floating spreader layer according to an embodiment of the present disclosure. FIG. 18A is a vertical cross-sectional view along the horizontal plane A-A′ of FIG. 17D and FIG. 18B is a vertical cross-sectional view along the horizontal plane B-B′ of FIG. 17D according to an embodiment of the present disclosure.

FIG. 19 is a top-down view of a seventeenth alternative structure including a patterned rectangular floating spreader layer according to an embodiment of the present disclosure.

FIG. 20 is a top-down view of an eighteenth alternative structure including a patterned diamond floating spreader layer 222 according to an embodiment of the present disclosure.

FIG. 21 is a top-down view of a nineteenth alternative structure including a patterned diamond floating spreader layer 222 according to an embodiment of the present disclosure.

FIG. 22 illustrates an exemplary block diagram of a Radio Frequency (RF) transceiver system, in accordance with some embodiments of the present disclosure.

FIG. 23 is a flowchart illustrating steps for forming a switch according to an embodiment of the present disclosure

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

A switch having a phase change material (PCM) layer may be used for switching between components in an electronic device. In particular, a phase change material radio frequency switch (PCM-RFS) may be used as a radio frequency (RF) switch in RF applications. Such RF applications may include, for example, switching RF components of a communication device between various RF configurations. A PCM-RFS may provide a lower off capacitance (C_{off}) than a typical complementary metal oxide semiconductor (CMOS) switch. A switch having a low C_{off} (and a low on resistance (Rₒₙ)) may be beneficial in RF applications in order to avoid signal leakage at high frequency.

In a typical switch, a voltage differential across nodes of a heater layer may result in electrical current flowing through the heater layer. Such current flow may create joule heating in a heater layer and generate about 1000K local temperature to change a phase of an adjacent PCM layer from amorphous phase (switch open/signal blocked) to crystalline phase (switch closed/signal pass). Generally, the switch may preferably have good thermal confinement in order to reduce power consumption. In order to revert the PCM layer back to the amorphous phase (e.g., reset the switch to an open state), a quick heat dissipation may be used to bring the switch (e.g., the PCM layer) from 1000K to 500K within about 100 ns after current removal. Such heat dissipation (also referred to as quenching) may typically be achieved by connecting an end of the heater layer to a large metal pad (heat sink) and/or adding a large spreader layer (e.g., metal spreader) beneath the heater layer. A design of a spreader layer (which may “spread” heat in the PCM-RFS) may, therefore, play and important role in a quenching operation of the PCM layer.

For example, a larger spreader layer may have better (i.e., faster) quenching capabilities to dissipate heat from the PCM layer 120 than a smaller spreader layer, and may therefore be faster at transitioning the PCM layer form an amorphous phase to a crystalline phase. However, the larger spreader layer 130 may have poor thermal confinement which and may therefore increase the power required to then transition the PCM layer back to an amorphous phase as compared to the smaller spreader layer. Thermal confinement may refer to the capabilities of a spreader to conduct heat from a PCM layer and evenly (i.e., uniformly) spread (i.e., dissipate), the conducted heat across itself. A spreader with poor thermal confinement (i.e., uneven/nonuniform heat distribution), as exhibited in spreaders with large areas such as whole-area spreaders, may therefore cause overheating issues and may subsequently increase the power required to transition a PCM between phases.

In addition, a typical switch may include a non-uniform distribution of thermal resistivity along the heater layer. That is, a thermal resistivity at a center of the heater layer (center Rth) may be greater than a thermal resistivity at an edge of the heater layer (edge Rth). A temperature gradient (e.g., a large temperature gradient (e.g., center and edge in one or both the X and Y direction) may be bad for reliability of the typical switch.

Various embodiments of the present disclosure are directed to switches, and particularly to switches including one or more floating spreader layers. Various embodiments may include a heater layer including a first heater pad, a second heater pad, and a heater line connecting the first heater pad and the second heater pad, a phase change material (PCM) layer positioned in a same vertical plane as the heater line, and a floating spreader layer including a first portion positioned in the same vertical plane as the heater line and the PCM layer, in which the first portion has a first width that is less than or equal to a distance between proximate sidewalls of the first heater pad and the second heater pad. Various embodiments may include a floating spreader layer of any size, shape, or thickness that may be fine-tuned to adjust the heat dissipation (i.e., quenching) properties of the floating spreader layer with respect to a PCM layer while minimizing the power used to transition the phases of the PCM layer. Thus, various embodiments include a floating spreader layer that may have dimensions and materials that (i) minimize power used to transition the PCM layer from an amorphous phase to a crytsalline phase (i.e., good thermal confinement), (ii) maximize the amount of thermal energy/heat dissipation from the PCM layer within a given period for transitioning from a crystalline phase to an amorphous phase (i.e., good thermal conduction), and/or (iii) minimize the transition times between amorphous and crystalline phases based on (i) and (ii).

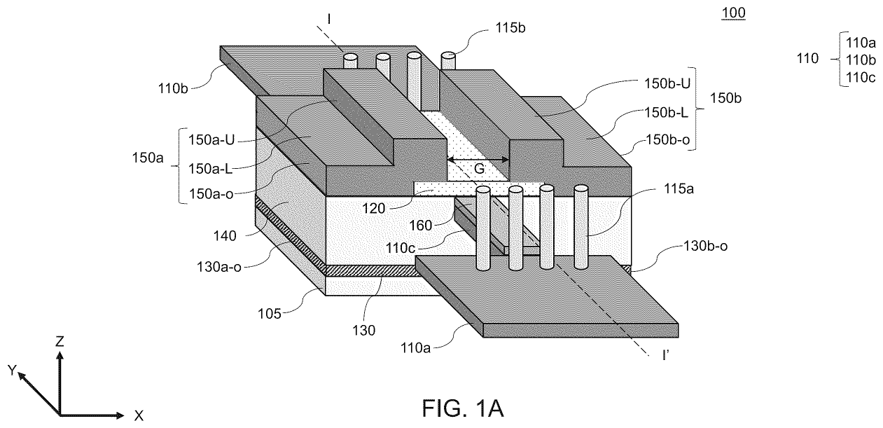

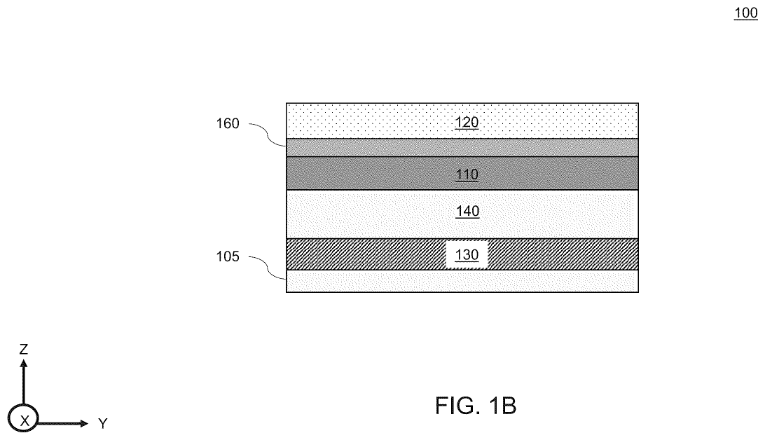

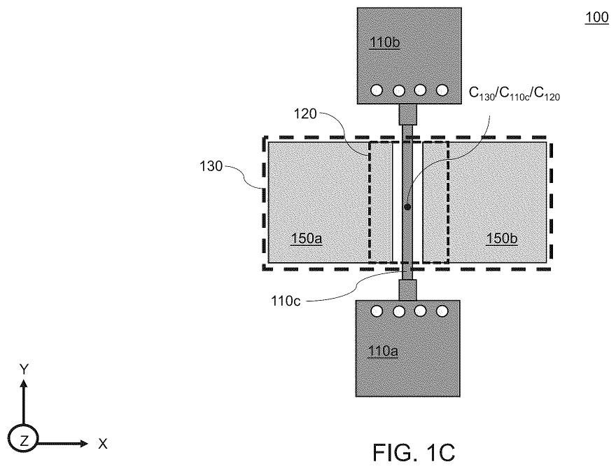

FIG. 1A is a perspective view of a switch 100 (e.g., a radio frequency (RF) switch) having a basic configuration, according to some embodiments of the present disclosure. FIG. 1B is a vertical cross-sectional view (with the x-direction into the page) of a portion of the switch 100 along the cross-section I-I′, according to some embodiments of the present disclosure. It should be noted that some elements of the switch 100 may be omitted from FIGS. 1A and 1B for ease of understanding.

The switch 100 (e.g., inline phase-change switch (IPCS)) may include a heater layer 110 (e.g., thin film resistor), a phase change material (PCM) layer 120 on the heater layer 110, and a floating spreader layer 130 formed below the heater layer 110. As illustrated in FIGS. 1A and 1B, an insulating layer 140 (thermally conductive and electrically insulating layer) may be located between the floating spreader layer 130 and the heater layer 110. The floating spreader layer 130 may alternatively or additionally be located on the PCM layer 120 (e.g., on an upper surface of the PCM layer 120).

The switch 100 may also include a positive signal contact 150a (e.g., positive signal pad or positive RF pad) on the PCM layer 120 and a negative signal contact 150b (e.g., negative signal pad or negative RF pad) on the PCM layer 120. In operation, a signal such as an RF signal may be transmitted from the positive signal contact 150a (e.g., RF input port) to the negative signal contact 150b (e.g., RF output port) through the PCM layer 120, in instances in which the PCM layer 120 is in a low resistive state (e.g., crystalline phase). The PCM layer 120 may not transmit the signal in instances in which the PCM layer 120 is in a high resistive state (e.g., amorphous phase).

As illustrated in FIGS. 1A and 1B, the floating spreader layer 130 may be located on an underlying substrate 105. The substrate 105 may include, for example, a semiconductor substrate (e.g., silicon, germanium, etc.), an oxide (e.g., silicon dioxide), a nitride (e.g., silicon nitride), etc. The substrate 105 may include, for example, one or more layers (e.g., a lower substrate layer and an upper substrate layer on the lower substrate layer).

The insulating layer 140 may be located on the floating spreader layer 130 and may include an insulator material with a thermal conductivity in a range from about 0.1 W/m·K to about 50 W/m·K (e.g., about 0.1 to 1.5 W/m·K). In particular, the insulating layer 140 may include an oxide layer such as silicon dioxide (e.g., SiO2), undoped silicate glass (USG) and/or other suitable insulating materials.

The heater layer 110 may include a positive heater contact 110a (e.g., positive heater pad) and a negative heater contact 110b (e.g., negative heater pad). The heater contacts 110a, 110b may be referred to as heater portions 110a, 110b, heater pads 110a, 110b, and or heating elements 110a, 110b. The positive heater contact 110a and negative heater contact 110b may be located on opposing sides of the switch 100 (e.g., in the y-direction). The positive heater contact 110a and negative heater contact 110b may be formed of substantially the same materials and have substantially the same size and shape. The positive heater contact 110a and negative heater contact 110b may be separated, for example, from the insulating layer 140. One or more metal vias 115a may contact a surface (e.g., upper surface) of the positive heater contact 110a. One or more metal vias 115b may contact a surface (e.g., upper surface) of the negative heater contact 110b. The metal vias 115a and metal vias 115b may be connected to a heat sink and help to dissipate heat from the heater contact 110a and the heater contact 110b, respectively. The metal vias 115a and metal vias 115b may be formed of copper, a copper alloy, or other suitable metal material.

The heater layer 110 may also include a heating portion 110c that extends from the positive heater contact 110a to the negative heater contact 110b. The heater portion 110c may be referred to as a heater line. The heating portion 110c may be located in (e.g., embedded in) the insulating layer 140 and below the PCM layer 120. The heating portion 110c may be integrally formed with the positive heater contact 110a and negative heater contact 110b. The heating portion 110c may be formed of the same materials as the positive heater contact 110a and negative heater contact 110b. The heating portion 110c may have substantially the same thickness (e.g., in the z-direction) as the positive heater contact 110a and negative heater contact 110b. The heating portion 110c may have width (e.g., in the x-direction) that is less than a width of the positive heater contact 110a and negative heater contact 110b.

The heater layer 110 (e.g., each of the positive heater contact 110a, negative heater contact 110b and heating portion 110c) may include a conductor with a thermal conductivity greater than about 175 W/m·K, a high melting point (e.g., greater than about 1500° C.) and a low Seebeck coefficient (e.g., less than about 20 ρV/K). The heater layer 110 may include tungsten, TiW or other metals or metal alloys, or other suitable conductive material.

The heating portion 110c may interact with the PCM layer 120 through a thermal dielectric layer 160 (e.g., electrical insulator with low dielectric constant and high thermal conductivity). The thermal dielectric layer 160 may separate the heating portion 110c from the PCM layer 120. In particular, a bottom surface of the thermal dielectric layer 160 may directly contact the heating portion 110c, and an upper surface of the thermal dielectric layer 160 may directly contact the PCM layer 120. The thermal dielectric layer 160 may have a thickness that is less than a thickness of the heating portion 110c. The thermal dielectric layer 160 may have a width in the x-direction that is substantially the same as a width of the heating portion 110c. The thermal dielectric layer 160 may optionally have a width in the x-direction that is greater than a width of the heating portion 110c. The thermal dielectric layer 160 may also have a length in the y-direction that is substantially the same as a length of the heating portion 110c.

The thermal dielectric layer 160 may increase a distance from the heating portion 110c to the positive signal contact 150a, the negative signal contact 150b, and the PCM layer 120. The thermal dielectric layer 160 may thereby help to reduce a parasitic capacitance coupling. A thermal path may be provided from the heating portion 110c to the PCM layer 120 by the thermal dielectric layer 160. The thermal dielectric layer 160 may be nonmetallic and electrically non-conductive and may include, for example, SiN, AlN, diamond-like carbon, SiC, and/or other suitable insulating materials. In particular, the thermal dielectric layer 160 may have a low dielectric constant (e.g., k in a range from about 3 to 10) and high thermal conductivity (e.g., greater than about 100 W/m·K).

In operation, a voltage differential may be created across the positive heater contact 110a and the negative heater contact 110b. For example, the positive heater contact 110a may be connected to a positive voltage and the negative heater contact 110b may be connected to a negative voltage. The resulting voltage drop between the positive heater contact 110a and negative heater contact 110b may generate joule heating in the heating portion 110c. In particular, a voltage pulse (e.g., input voltage or input bias) may create current for joule heating in the heating portion 110c and generate a local temperature of about 1000K or more. The heat generated by the joule heating in the heating portion 110c may heat the PCM layer 120 (e.g., through the thermal dielectric layer 160) so as to cause a phase change of the PCM layer 120 (from crystalline phase to amorphous phase, and vice versa), and thereby change the resistivity of the PCM layer 120. Subsequent cooling (i.e., quenching) may transition the PCM layer 120 from an amorphous phase to a crystalline phase, thereby changing the resistivity of the PCM layer 120 again.

The heating portion 110c and thermal dielectric layer 160 may be substantially embedded in the insulating layer 140. That is, the insulating layer 140 may contact both sidewalls of the heating portion 110c in the x-direction, and may contact a bottom surface of the heating portion 110c in the z-direction. The insulating layer 140 may also contact both sidewalls of the thermal dielectric layer 160 in the x-direction. An upper surface of the insulating layer 140 may be substantially coplanar with the upper surface of the thermal dielectric layer 160. The upper surface of the insulating layer 140 adjacent to the heating portion 110c may also contact a bottom surface of the PCM layer 120.

The PCM layer 120 may be located on or over the heating portion 110c and (optionally) on or over the insulating layer 140. The PCM layer 120 may have a length in the y-direction that is less than a length of the heating portion 110c, and substantially the same as a length of the insulating layer 140. The PCM layer 120 may have a width in the x-direction that is greater than a width of the heating portion 110c. In at least one embodiment, the width of the PCM layer 120 in the x-direction may be at least 50% greater than the width of the heating portion 110c. The PCM layer 120 may also have a thickness in the z-direction that is less than a thickness of the heater portion 110c. A central region of the PCM layer 120 may be located on the heating portion 110c (e.g., on the thermal dielectric layer 160). In particular, a center point of the PCM layer 120 (in the x-direction and y-direction) may be substantially aligned with a center point of the heating portion 110c. The PCM layer 120 may have a thermal conductivity in a range from about 2.5 W/m·K to about 10. The PCM layer 120 may include GeTe, GeSeTe (GST), hafnium-doped zinc oxide (HZO), and/or other suitable phase change materials.

The positive signal contact 150a may be located on the insulating layer 140 and on the PCM layer 120. The positive signal contact 150a may have a stepped configuration and include a lower positive signal contact portion 150a-L and an upper positive signal contact portion 150a-U. The lower positive signal contact portion 150a-L may be located on and contact an upper surface of the insulating layer 140 and may abut a first outer sidewall of the PCM layer 120. The upper positive signal contact portion 150a-U may be located on and contact an upper surface of the PCM layer 120. In at least one embodiment, the upper positive signal contact portion 150a-U may contact at least 20% of the upper surface of the PCM layer 120 in order to ensure an adequate contact with the PCM layer 120. The lower positive signal contact portion 150a-L may be integrally formed with the upper positive signal contact portion 150a-U. The lower positive signal contact portion 150a-L may be connected (e.g., seamlessly connected) to the upper positive signal contact portion 150a-U at the outer sidewall of the PCM layer 120.

The negative signal contact 150b may be located on an opposing side (in the x-direction) of the switch 100 from the positive signal contact 150a. The negative signal contact 150b may also be located on the insulating layer 140 and on the PCM layer 120. The negative signal contact 150b may also have a stepped configuration and may include a lower negative signal contact portion 150b-L and an upper negative signal contact portion 150b-U. The lower negative signal contact portion 150b-L may be located on and contact the upper surface of the insulating layer 140 and may abut a second outer sidewall of the PCM layer 120 that is opposite the first outer sidewall of the PCM layer 120. The upper negative signal contact portion 150b-U may also be located on and contact the upper surface of the PCM layer 120. In at least one embodiment, the upper negative signal contact portion 150b-U may contact at least 20% of the upper surface of the PCM layer 120 in order to ensure an adequate contact with the PCM layer 120. The lower negative signal contact portion 150b-L may be integrally formed with the upper negative signal contact portion 150b-U. The lower negative signal contact portion 150b-L may be connected (e.g., seamlessly connected) to the upper negative signal contact portion 150b-U at the outer sidewall of the PCM layer 120.

An inner sidewall of the upper positive signal contact portion 150a-U may face an inner sidewall of the upper negative signal contact portion 150b-U over the PCM layer 120. In at least one embodiment, a gap G between the inner sidewall of the upper positive signal contact portion 150a-U and the inner sidewall of the upper negative signal contact portion 150b-U may be greater than a width of the heating portion 110c in the x-direction. In some embodiments, the gap G may be less than or equal to a width of the heating portion 110c in the x-direction.

The positive signal contact 150a may have a thickness that is substantially the same as a thickness of the negative signal contact 150b. The thickness of the positive signal contact 150a and negative signal contact 150b may be greater than a thickness of the PCM layer 120. The positive signal contact 150a and negative signal contact 150b may be formed of the same conductive material. In particular, the positive signal contact 150a and negative signal contact 150b may be formed of tungsten and/or other suitable conductive materials.

The floating spreader layer 130 may include, for example, a substrate (e.g., RF substrate) for the switch 100. The floating spreader layer 130 may be thermally conductive and help to dissipate heat in the heating portion 110c generated by joule heating. In this manner, the floating spreader layer 130 may be said to cool or quench the PCM layer 120. In various embodiments, the floating spreader layer 130 may be floating within oxide such that the floating spreader layer is fully encapsulated by one or more oxide layers (e.g., insulating layer 140). In other words, the floating spreader layer 130 may have sidewalls, a bottom surface, and a top surface that is in contact with and is encapsulated by one or more oxide layers.

The floating spreader layer 130 may have an outer periphery that is substantially coextensive with an outer periphery of the positive signal contact 150a and negative signal contact 150b. For example, the floating spreader layer 130 may be centrally positioned above or below a central point between the positive signal contact 150a and negative signal contact 150b and may extend beyond an outer periphery 150a-o of the positive signal contact 150a and an outer periphery 150b-o of the negative signal contact 150b in the x-direction. In some embodiments, the floating spreader layer 130 may have an outer periphery in the x-direction defined by a first floating spreader outer sidewall 130a-o and a second floating spreader outer sidewall 130b-o, in which the outer periphery of the floating spreader layer 130 is substantially coextensive with an outer periphery of the an outer periphery 150a-o of the positive signal contact 150a and an outer periphery 150b-o of the negative signal contact 150b. In some embodiments, the first floating spreader outer sidewall 130a-o and the second floating spreader outer sidewall 130b-o may be vertically aligned with the outer periphery 150a-o of the positive signal contact 150a and the outer periphery 150b-o of the negative signal contact 150b. In some embodiments, the floating spreader layer 130 may have an outer periphery that is substantially coextensive with an outer periphery of the PCM layer 120. For example, the floating spreader layer 130 may be centrally positioned above or below the PCM layer 120 and may extend beyond the outer peripherals of the PCM layer 120 or may be vertically aligned with the outer peripherals of the PCM layer 120. In some embodiments, the floating spreader layer 130 may have an outer periphery that is within an outer periphery of the positive signal contact 150a and negative signal contact 150b, such that the floating spreader layer 130 is confined within a vertical plane above or below the outer periphery of the positive signal contact 150a and negative signal contact 150b. In some embodiments, the floating spreader layer 130 may have an outer periphery that is within an outer periphery of the PCM layer 120, such that the floating spreader layer 130 is confined within a vertical plane above or below the outer periphery of the PCM layer 120.

In at least one embodiment, the floating spreader layer 130 may have a thickness in the z-direction that is less than the thickness of the heater layer 110. In at least one embodiment, the floating spreader layer 130 may have a thickness in the z-direction that is less than the thickness of the PCM layer 120.

The floating spreader layer 130 may be designed to have dimensions that correspond to a thermal resistivity of the heating portion 110c. The design of the floating spreader layer 130 may help to provide a substantially uniform distribution of thermal resistivity (e.g., in the x-direction and/or in the y-direction) in the heater layer 110 (e.g., in the heating portion 110c), thereby improving a reliability of the switch 100 and avoiding an over-heating issue that may be common in a typical switch.

FIG. 1C is a plan view (e.g., top-down view) of the switch 100 including the floating spreader layer 130, according to some embodiments of the present disclosure. As illustrated in FIG. 1C, a length of the floating spreader layer 130 in the y-direction may be less than a length of the heating portion 110c. A width of the floating spreader layer 130 in the x-direction may be greater than (as illustrated), equal to, or less than a combined width of the positive heater contact 110a and/or the negative heater contact 110b measured along the x-direction. A center point C₁₃₀ of the floating spreader layer 130 may be substantially aligned with a center point C_{130c} of the heating portion 110c and a center point C₁₂₀ of the PCM layer 120. The central region of the floating spreader layer 130 may be substantially aligned with a central region of the heating portion 110c and with a central region of the PCM layer 120.

An operation of the switch 100 including the floating spreader layer 130 will now be briefly described. In operation, a setting voltage pulse may be applied to the heater layer 110 (e.g., across the positive heater contact 110a and negative heater contact 110b). The setting voltage pulse may have a duration of about 1 μs and increase a temperature of the PCM layer 120 to about a crystallization temperature (about 500K) of the PCM layer 120. As a result, the PCM layer 120 may be set to a crystalline phase having a low resistivity so that the switch 100 may be closed. With the switch 100 closed, a signal (e.g., RF signal) may be transmitted from the positive signal contact 150a to the negative signal contact 150b through the PCM layer 120.

A resetting voltage pulse may then be applied to the heater layer 110 (e.g., across the positive heater contact 110a and negative heater contact 110b). The resetting voltage pulse may include a greater voltage than the setting voltage pulse. The resetting voltage pulse may have a duration of about 150 ns and increase a temperature of the PCM layer 120 to about a melting temperature (about 1000K) of the PCM layer 120. A switching off of the heater layer 110 may cause a decrease in a temperature of the PCM layer 120 from about 1000K to about 500K within 100 ns. As a result, the PCM layer 120 may be reset to an amorphous phase having a high resistivity so that the switch 100 may be opened. With the switch 100 open, a signal (e.g., RF signal) may be blocked from transmission from the positive signal contact 150a to the negative signal contact 150b through the PCM layer 120.

In order to reset the PCM layer 120 to the amorphous phase, it may be needed to rapidly quench the melted PCM layer 120. The floating spreader layer 130 may dissipate heat from the PCM layer 120 and may, therefore, play an important role in the quenching of the PCM layer 120. The floating spreader layer 130 may, therefore, may play an important role in resetting of the PCM layer 120 to the amorphous phase.

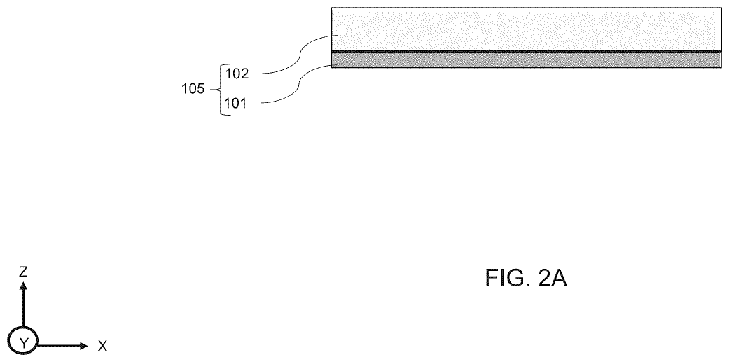

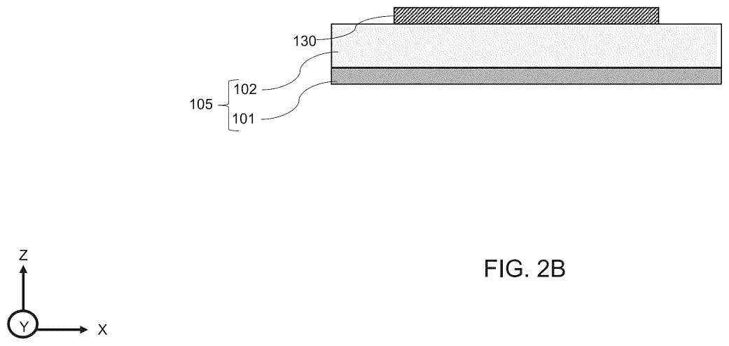

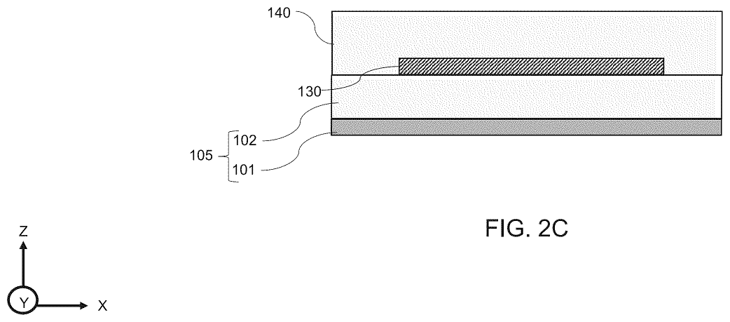

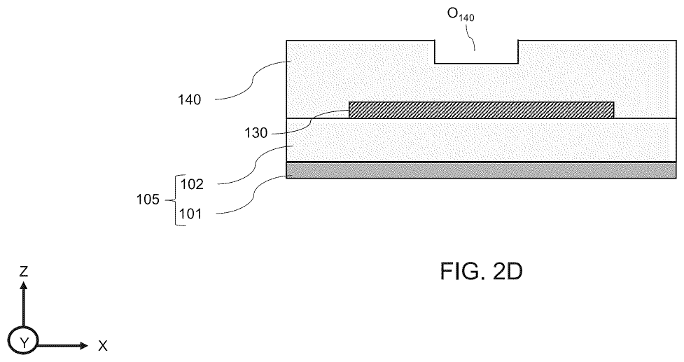

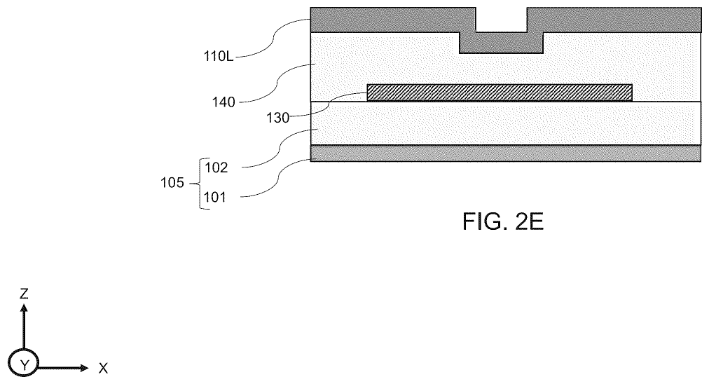

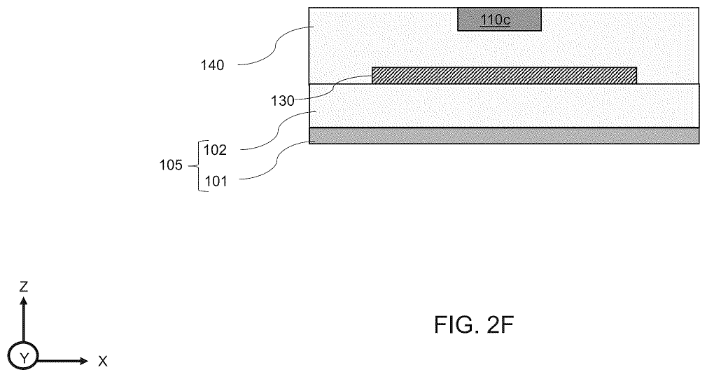

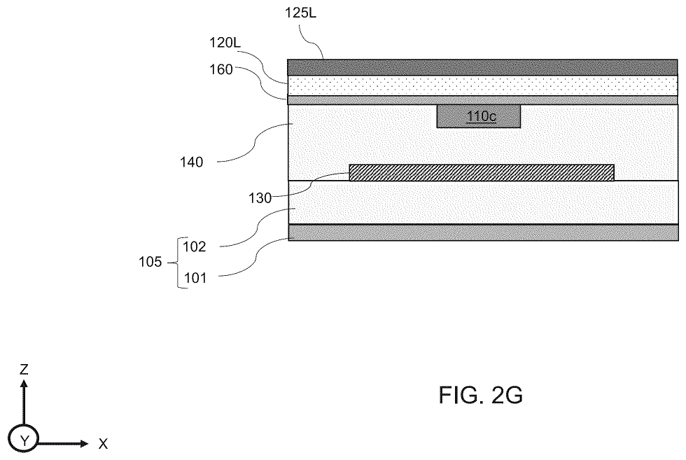

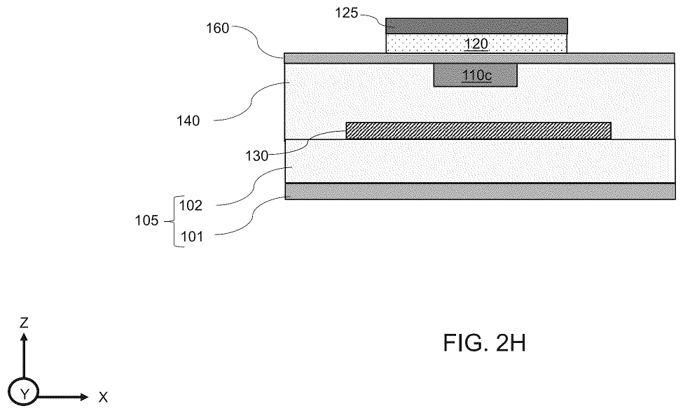

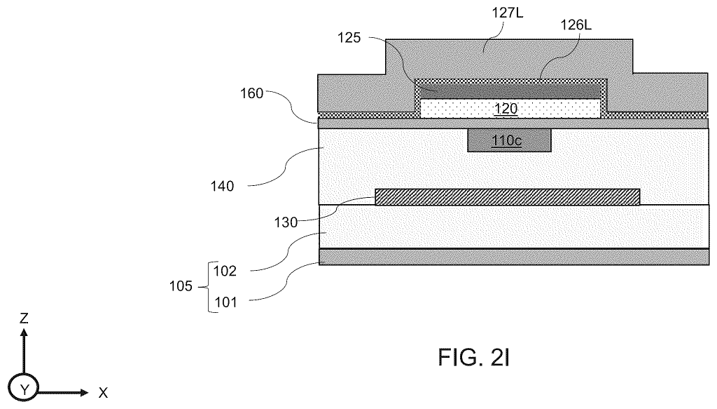

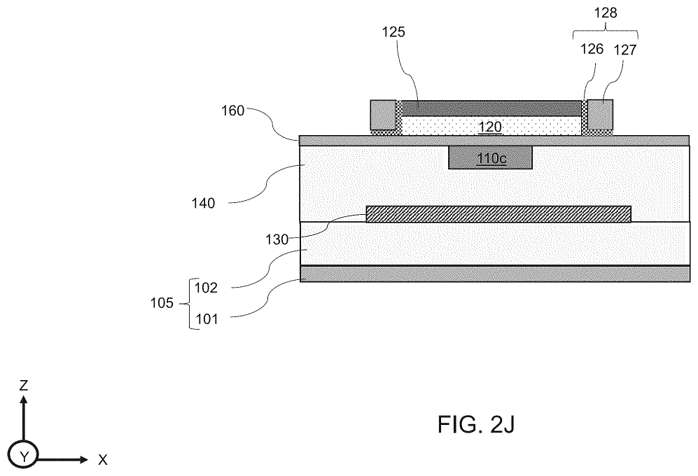

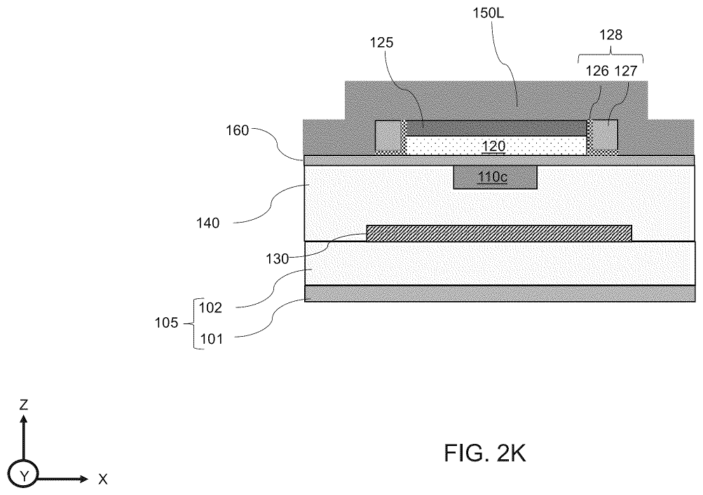

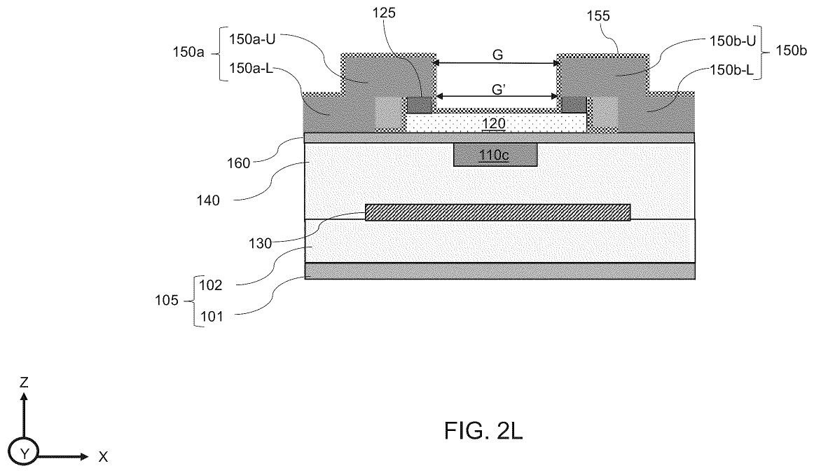

FIGS. 2A-2L are vertical cross-sectional views of intermediate structures in a method of forming a switch (e.g., switch 100), according to some embodiments of the present disclosure. In particular, FIG. 2A is a vertical cross-sectional view of an intermediate structure including the substrate 105, according to some embodiments of the present disclosure. As illustrated in FIG. 2A, the substrate 105 may include, for example, a lower substrate layer 101 and an upper substrate layer 102 on the lower substrate layer 101.

The lower substrate layer 101 may include, for example, silicon nitride or other suitable materials. A thickness of the lower substrate layer 101 is not necessarily limited. The lower substrate layer 101 may be deposited (e.g., on a carrier substrate) by thin film creation such as by chemical vapor deposition (CVD), plasma-enhanced CVD (PECVD), low pressure chemical vapor deposition (LPCVD), physical vapor deposition (PVD) (e.g., sputtering) or atomic layer deposition (ALD). The upper substrate layer 102 may include, for example, an oxide such as silicon dioxide or other suitable materials. A thickness of the upper substrate layer 102 is not necessarily limited. The upper substrate layer 102 may also be formed, for example, by thin film creation such as by chemical vapor deposition (CVD), plasma-enhanced CVD (PECVD), low pressure chemical vapor deposition (LPCVD), physical vapor deposition (PVD) (e.g., sputtering) or atomic layer deposition (ALD).

FIG. 2B is a vertical cross-sectional view of an intermediate structure including the floating spreader layer 130, according to some embodiments of the present disclosure. The floating spreader layer 130 may be formed on the surface of the substrate 105. To form the floating spreader layer 130, a layer of thermally conductive material (e.g., a compound such as SiC and/or metal such as copper, and/or other thermally conductive materials or metals with a thermal conductivity greater than 100 W/mK) may be formed on the surface of the substrate 105. The layer of thermally conductive material may be deposited to have a thickness in a range from 0.05 μm to about 1 μm. The layer of thermally conductive material may be formed, for example, by thin film creation such as by chemical vapor deposition (CVD), plasma-enhanced CVD (PECVD), low pressure chemical vapor deposition (LPCVD), physical vapor deposition (PVD) (e.g., sputtering) or atomic layer deposition (ALD).

The layer of thermally conductive material may then be patterned to have a desired metal pattern and shape according to the various embodiments described herein. The thermally conductive material may be patterned by etching. The etching may be performed, for example, by a photolithographic process that may include forming a patterned photoresist mask (not shown) on the layer of thermally conductive material so that an upper surface of the layer of thermally conductive material is exposed through openings in the photoresist mask. Then, the exposed upper surface of the layer of thermally conductive material may be etched (e.g., by wet etching, dry etching, etc.) through the openings in the photoresist mask. The photoresist mask may be subsequently removed by ashing, dissolving the photoresist mask or by consuming the photoresist mask during the etch process.

In some embodiments, the layer of thermally conductive material may be deposited within a cavity formed within the upper substrate layer 102. For example, a hole, gap, or cavity may be etched (e.g., with a mask) within the upper substrate layer 102 to have dimensions equal to or slightly greater than the desired dimensions of the subsequently formed floating spreader layer 130. The thermally conductive material may then be deposited within the cavity, and any excess amount of thermally conductive material may be removed, for example, by chemical mechanical polishing (CMP) and/or other suitable planarization methods. After the planarization, the upper surface of the upper substrate layer 102 and the thermally conductive material may be smoothed by buffing (e.g., touch-up polishing), such that a top surface of the upper substrate layer 102 is coplanar with a top surface of the floating spreader layer 130.

FIG. 2C is a vertical cross-sectional view of an intermediate structure including the insulating layer 140, according to some embodiments of the present disclosure. The insulating layer 140 may have a structure (e.g., thickness, materials) similar to the structure as the upper substrate layer 102. As illustrated in FIG. 2C, the insulating layer 140 may be formed on a top surface of the floating spreader layer 130 and around sidewalls of the floating spreader layer 130. The insulating layer 140 may be formed on top exposed surfaces of the substrate 105 to encapsulate the floating spreader layer 130 within the insulating layer 140 and the substrate 105. A thickness of the insulating layer 140 measured from the surface of the substrate 105 may be equal to or greater than a thickness of the floating spreader layer 130. In at least one embodiment, the thickness of the insulating layer 140 may be at least twice the thickness of the floating spreader layer 130. The insulating layer 140 may be formed, for example, by thin film creation such as by chemical vapor deposition (CVD), plasma-enhanced CVD (PECVD), low pressure chemical vapor deposition (LPCVD), physical vapor deposition (PVD) (e.g., sputtering) or atomic layer deposition (ALD).

FIG. 2D is a vertical cross-sectional view of an intermediate structure including an opening O₁₄₀ in the insulating layer 140, according to some embodiments of the present disclosure. The opening O₁₄₀ (e.g., heater trench) may be formed in the upper surface of the insulating layer 140. The opening O₁₄₀ may be formed in substantially the same location (e.g., a central portion of the insulating layer 140) and have substantially the same design as the subsequently-formed heating portion 110c. The opening O₁₄₀ may extend across an entire length of the insulating layer 140 in the y-direction. A depth of the opening O₁₄₀ in the z-direction may be less than a thickness of the insulating layer 140. In at least one embodiment, the depth of the opening O₁₄₀ may be substantially the same as the combined thickness of the subsequently-formed heating portion 110c and thermal dielectric layer 160.

The opening O₁₄₀ may be formed in the insulating layer 140 by etching. The etching may be performed, for example, by a photolithographic process. The photolithographic process may include forming a patterned photoresist mask (not shown) on the insulating layer 140 so that an upper surface of the insulating layer 140 is exposed through openings in the photoresist mask. Then, the exposed upper surface of the insulating layer 140 may be etched (e.g., by wet etching, dry etching, etc.) through the openings in the photoresist mask. The photoresist mask may be subsequently removed by ashing, dissolving the photoresist mask or by consuming the photoresist mask during the etch process.

FIG. 2E is a vertical cross-sectional view of an intermediate structure including a layer of heater material 110L, according to some embodiments of the present disclosure. The layer of heater material 110L may be formed on a surface of the insulating layer 140. The layer of heater material 110L may be formed in the opening O₁₄₀ and substantially fill the opening O₁₄₀. That is, a thickness of the layer of heater material 110L may be at least greater than a depth of the opening O₁₄₀. The layer of heater material 110L may include, for example, tungsten, TiW or other metals or metal alloys, or other suitable conductive material. The layer of heater material 110L may be formed, for example, by thin film creation such as by chemical vapor deposition (CVD), plasma-enhanced CVD (PECVD), low pressure chemical vapor deposition (LPCVD), physical vapor deposition (PVD) (e.g., sputtering) or atomic layer deposition (ALD).

It should be noted that prior to forming the layer of heater material 110L, a heater barrier layer (not shown) may optionally be formed (e.g., conformally formed) on the insulating layer 140 and in the opening O₁₄₀. The heater barrier layer may include, for example, titanium nitride (TiN), tantalum nitride (TaN), and/or other suitable diffusion barrier materials. The heater barrier layer may also be formed by thin film creation such as by chemical vapor deposition (CVD), plasma-enhanced CVD (PECVD), low pressure chemical vapor deposition (LPCVD), physical vapor deposition (PVD) (e.g., sputtering) or atomic layer deposition (ALD).

FIG. 2F is a vertical cross-sectional view of an intermediate structure including the heating portion 110c of the heater layer 110, according to some embodiments of the present disclosure. The layer of heater material 110L on the surface of the insulating layer 140 may be removed so that the upper surface of the heating portion 110c is substantially co-planar with the upper surface of the insulating layer 140. The layer of heater material 110L may be removed, for example, by CMP and/or other suitable planarization methods. After the planarization, the upper surface of the heating portion 110c and/or the upper surface of the insulating layer 140 may be smoothed by buffing (e.g., touch-up polishing). It should be noted that the positive heater contact 110a and negative heater contact 110b may or may not be formed concurrently with the forming of the heating portion 110c.

FIG. 2G is a vertical cross-sectional view of an intermediate structure including the thermal dielectric layer 160 and a layer of PCM 120L, according to some embodiments of the present disclosure. To form the thermal dielectric layer 160, a layer of nonmetallic and electrically non-conductive material such as SiN, AlN, diamond-like carbon, SiC, etc. may be formed on the upper surface of the insulating layer 140 and the upper surface of the heating portion 110c. The thermal dielectric layer 160 may be formed by thin film creation such as by chemical vapor deposition (CVD), plasma-enhanced CVD (PECVD), low pressure chemical vapor deposition (LPCVD), physical vapor deposition (PVD) (e.g., sputtering) or atomic layer deposition (ALD).

It should be noted that the thermal dielectric layer 160 may alternatively be formed in the heater opening O₁₄₀ on the heating portion 110c (e.g., see FIG. 2D and FIG. 2E). In that case, an upper surface of the thermal dielectric layer 160 may be planarized (e.g., by CMP) to be substantially coplanar with an upper surface of the insulating layer 140 as shown in FIG. 1A.

A layer of PCM 120L may then be formed on the thermal dielectric layer 160. The layer of PCM 120L may be formed, for example, by depositing GeTe, GeSeTe (GST), hafnium-doped zinc oxide (HZO), and/or other suitable phase change material, on the thermal dielectric layer 160. A layer of PCM barrier 125L (not shown in FIG. 1A) may then optionally be formed on the layer of PCM 120L. The layer of PCM barrier 125L may be formed, for example, by depositing a layer of titanium nitride (TiN), tantalum nitride (TaN), and/or other suitable diffusion barrier materials on the layer of PCM 120L. A thickness of the layer of PCM barrier 125L may be less than a thickness of the layer of PCM 120L. Each of the layer of PCM 120L and the layer of PCM barrier layer 125 may be individually formed by thin film creation such as by chemical vapor deposition (CVD), plasma-enhanced CVD (PECVD), low pressure chemical vapor deposition (LPCVD), physical vapor deposition (PVD) (e.g., sputtering) or atomic layer deposition (ALD).

FIG. 2H is a vertical cross-sectional view of an intermediate structure including the PCM layer 120, according to some embodiments of the present disclosure. The layer of PCM 120L and the layer of PCM barrier layer 125L may be etched to form (e.g., define) the PCM layer 120 and a PCM barrier layer 125 on the PCM layer 120, respectively. The etching may be performed, for example, by one or more photolithographic processes. The photolithographic processes may include forming a patterned photoresist mask (not shown) on the layer of PCM barrier 125L so that an upper surface of the layer of PCM barrier 125L is exposed through openings in the photoresist mask. Then, the exposed upper surface of the layer of PCM barrier 125L and the underlying layer of PCM 120L may be etched (e.g., by wet etching, dry etching, etc.) through the openings in the photoresist mask. The photoresist mask may be subsequently removed by ashing, dissolving the photoresist mask or by consuming the photoresist mask during the etch process.

FIG. 2I is a vertical cross-sectional view of an intermediate structure including a layer of bottom spacer material 126L and a layer of upper spacer material 127L, according to some embodiments of the present disclosure. The layer of bottom spacer material 126L and layer of upper spacer material 127L may optionally be used to form a PCM sidewall spacer that is not shown, for example, FIG. 1A.

The layer of bottom spacer material 126L (not shown in FIG. 1A) may optionally be formed (e.g., conformally formed) on the PCM layer 120 and PCM barrier layer 125. The layer of bottom spacer material 126L may be formed, for example, by depositing a layer of oxide (e.g., silicon dioxide) or other suitable spacer material on an upper surface of the PCM barrier layer 125, on a sidewall of the PCM barrier layer 125, on a sidewall of the PCM layer 120, and on the upper surface of the thermal dielectric layer 160. A thickness of the layer of bottom spacer material 126L may be less than a thickness of the PCM barrier layer 125. The layer of bottom spacer material 126L may be formed by thin film creation such as by chemical vapor deposition (CVD), plasma-enhanced CVD (PECVD), low pressure chemical vapor deposition (LPCVD), physical vapor deposition (PVD) (e.g., sputtering) or atomic layer deposition (ALD).

A layer of upper spacer material 127L may then optionally be formed (e.g., conformally formed) on the layer of bottom spacer material 126L. The layer of upper spacer material 127L may be formed, for example, by depositing a layer of nitride (e.g., silicon nitride) or other suitable spacer material on an upper surface of the layer of bottom spacer material 126L. A thickness of the layer of upper spacer material 127L may be greater than a thickness of the layer of bottom spacer material 126L. The layer of upper spacer material 127L may be formed by thin film creation such as by chemical vapor deposition (CVD), plasma-enhanced CVD (PECVD), low pressure chemical vapor deposition (LPCVD), physical vapor deposition (PVD) (e.g., sputtering) or atomic layer deposition (ALD).

FIG. 2J is a vertical cross-sectional view of an intermediate structure including a bottom spacer 126 and an upper spacer 127 according to some embodiments of the present disclosure. The layer of bottom spacer material 126L and the layer of upper spacer material 127L may be etched to form (e.g., define) the bottom spacer 126 and the upper spacer 127 on the sidewall of the PCM layer 120 and the PCM barrier layer 125. The bottom spacer 126 and the upper spacer 127 may together form a PCM sidewall spacer 128.

The etching may be performed such that an upper surface of the bottom spacer 126 and an upper surface of the upper spacer 127 may be substantially coplanar with the upper surface of the PCM barrier layer 125. The etching may be performed, for example, by a photolithographic process. The photolithographic process may include forming a patterned photoresist mask (not shown) on the layer of upper spacer material 127L so that an upper surface of the layer of upper spacer material 127L is exposed through openings in the photoresist mask. Then, the exposed upper surface of the layer of upper spacer material 127L and the underlying layer of bottom spacer material 126L may be etched (e.g., by wet etching, dry etching, etc.) through the openings in the photoresist mask. The photoresist mask may be subsequently removed by ashing, dissolving the photoresist mask or by consuming the photoresist mask during the etch process. In some embodiments, the layer of bottom spacer material 126L and the layer of upper spacer material 127L may be etched using a maskless anisotropic etching process to form (e.g., define) the bottom spacer 126 and the upper spacer 127.

FIG. 2K is a vertical cross-sectional view of an intermediate structure including a layer of signal contact material 150L, according to some embodiments of the present disclosure. The layer of signal contact material 150L may be formed on the upper surface of the thermal dielectric layer 160, an upper surface of the PCM sidewall spacers 128, and the upper surface of the PCM barrier layer 125. The layer of signal contact material 150L may be formed, for example, by depositing a layer of tungsten and/or other suitable signal contact material on the upper surface of the thermal dielectric layer 160, the upper surface of the PCM sidewall spacers 128, and the upper surface of the PCM barrier layer 125. In at least one embodiment, a thickness of the layer of signal contact material 150L may be greater than a thickness of the PCM sidewall spacers 128 (e.g., a combined thickness of the PCM layer 120 and the PCM barrier layer 125). The layer of signal contact material 150L may be formed by thin film creation such as by chemical vapor deposition (CVD), plasma-enhanced CVD (PECVD), low pressure chemical vapor deposition (LPCVD), physical vapor deposition (PVD) (e.g., sputtering) or atomic layer deposition (ALD).

FIG. 2L is a vertical cross-sectional view of an intermediate structure including the positive signal contact 150a and the negative signal contact 150b, according to some embodiments of the present disclosure. As illustrated in FIG. 2K, a central portion of the layer of signal contact material 150L that is over the PCM layer 120 may be removed. A central portion of the PCM barrier layer 125 may be removed concurrently with (or subsequent to) the removal of the central portion of the layer of signal contact material 150L.

An etching may be performed in order to remove the central portion of the layer of signal contact material 150L and the central portion of the PCM barrier layer 125. The etching may be performed, for example, by one or more photolithographic processes. The photolithographic processes may include forming a patterned photoresist mask (not shown) on the layer of signal contact material 150L so that an upper surface of the layer of signal contact material 150L is exposed through openings in the photoresist mask. Then, the exposed upper surface of the layer of signal contact material 150L and the underlying PCM barrier layer 125 may be etched (e.g., by wet etching, dry etching, etc.) through the openings in the photoresist mask. The photoresist mask may be subsequently removed by ashing, dissolving the photoresist mask or by consuming the photoresist mask during the etch process.

The etching of the layer of signal contact material 150L may define the positive signal contact 150a (upper positive signal contact portion 150a-U and lower positive signal contact portion 150a-L) and negative signal contact 150b (upper negative signal contact portion 150b-U and lower negative signal contact portion 150b-L). The etching may also define the gap G between the inner sidewall of the upper positive signal contact portion 150a-U and the inner sidewall of the upper negative signal contact portion 150b-U. The etching of the PCM barrier layer 125 may also expose inner sidewalls of the PCM barrier layer 125 that may be substantially aligned with the inner sidewall of the upper positive signal contact portion 150a-U and the inner sidewall of the upper negative signal contact portion 150b-U.

A contact protective layer 155 (e.g., passivation layer) may optionally be formed on an upper surface of the positive signal contact 150a, an upper surface of the negative signal contact 150b, and the upper surface of the PCM layer 120. The contact protective layer 155 may also be formed on the inner sidewall of the upper positive signal contact portion 150a-U, the inner sidewall of the upper negative signal contact portion 150b-U, and the inner sidewalls of the PCM barrier layer 125. A gap G′ (slightly less than the gap G) may be formed between sidewall portions of the contact protective layer 155 in the gap G. The contact protective layer 155 may be formed, for example, by depositing a thin layer of protective material (e.g., SiN) on those surfaces and sidewalls. The contact protective layer 155 may be formed by thin film creation such as by chemical vapor deposition (CVD), plasma-enhanced CVD (PECVD), low pressure chemical vapor deposition (LPCVD), physical vapor deposition (PVD) (e.g., sputtering) or atomic layer deposition (ALD).

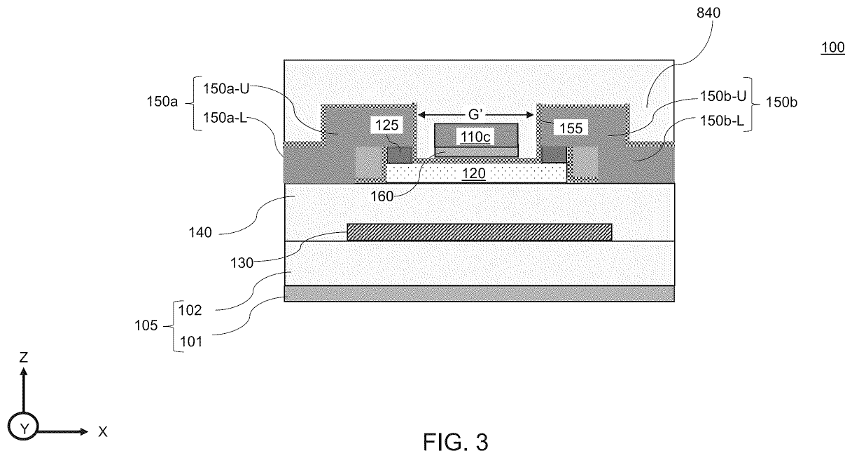

FIG. 3 is a vertical cross-sectional view (with the y-direction into the page) of the switch 100 having a first alternative structure, according to some embodiments of the present disclosure. A floating spreader layer 130 may be implemented in a switch 100 including a heating portion 110c that is positioned vertically above the PCM layer 120. For example, instead of including the heating portion 110c and thermal dielectric layer 160 below the PCM layer 120 (e.g., between the spreader layer 130 and the PCM layer 120) as is illustrated in FIGS. 2H-2L, the heating portion 110c and thermal dielectric layer 160 may be located above the PCM layer 120. That is, the heating portion 110c and the thermal dielectric layer 160 may be located on the PCM layer 120 between the positive signal contact 150a and the negative signal contact 150b.

In particular, the thermal dielectric layer 160 may be located on PCM layer 120 (e.g., on the contact protective layer 155) in the gap G′ or in the gap G (see FIG. 1A). The heating portion 110c may be located on the thermal dielectric layer 160. The structure and function of the heating portion 110c and the thermal dielectric layer 160 may be substantially the same. However, a width of the thermal dielectric layer 160 in the first alternative structure may be less than the width of the thermal dielectric layer 160 as described with reference to FIGS. 2G-2L. The upper insulating layer 840 may be located on the upper surface and sidewalls of the heating portion 110c and on the sidewalls of the thermal dielectric layer 160. The upper insulating layer 840 may have a thickness in the gap G′ that is greater than or equal to a combined thickness of the heating portion 110c and the thermal dielectric layer 160.

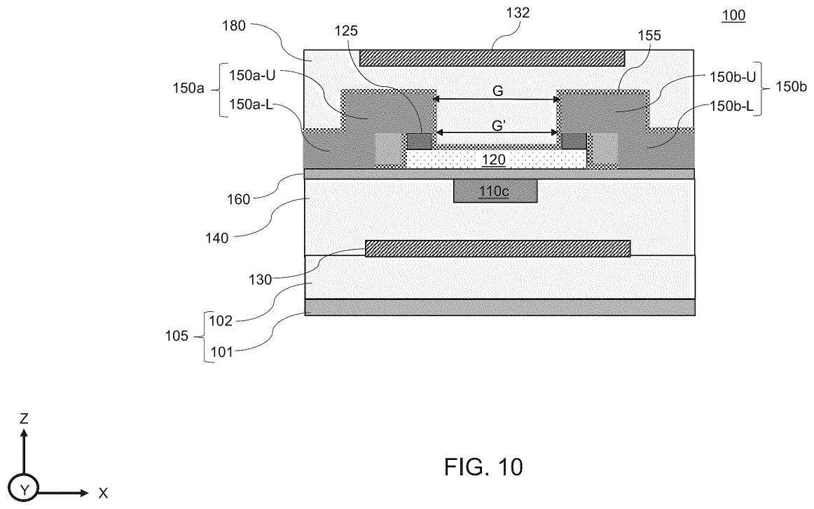

It should be noted that while the first alternative structure of the switch 100 includes the heating portion 110c positioned above the PCM layer 120 and the floating spreader layer 130, additional configurations regarding the relative positioning and formation of the heating portion 110c, PCM layer 120, and floating spreader layer 130 (and any additional spreader layers) are contemplated within the present disclosure. For example, it would be obvious to one of ordinary skill in the art to implement the various embodiments and alternative structures (e.g., as described with reference to FIGS. 10-20) as including a heating portion 110c positioned above the PCM layer 120 instead of below the PCM layer 120 (as illustrated in FIGS. 10-20). Furthermore, it would be obvious to one of ordinary skill in the art to modify the structures and processes as described with reference to FIGS. 1A-2L to form the heating portion 110c above the PCM layer 120.

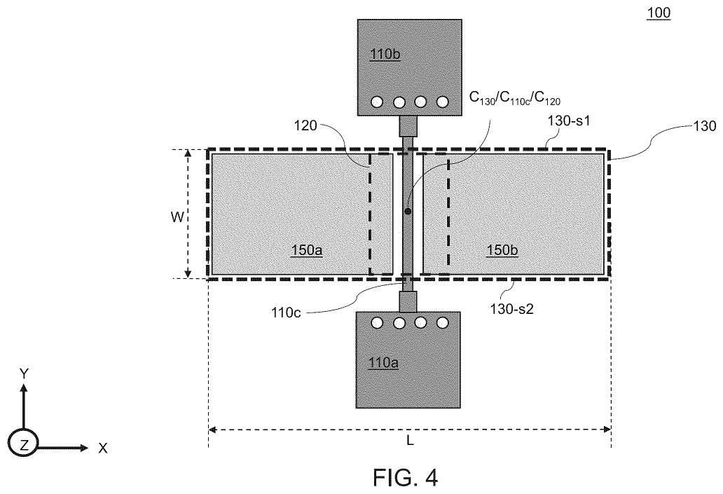

FIGS. 4-9 are various top-down views of alternate structures including a floating spreader layer 130 according to some embodiments of the present disclosure. For ease of illustration, the PCM layer 120 and the floating spreader layer 130 are depicted as dashed lines to illustrate the peripheries of the various components relative to other components within the switch 100 with respect to the z-direction.

Referring to FIGS. 4-9, the floating spreader layer 130 may have a width (i.e., dimension in the y-direction) that is the same or substantially the same as a width of the PCM layer 120. In some embodiments, the width of the floating spreader layer 130 may be less than the width of the PCM layer 120. In some embodiments, the width of the floating spreader layer 130 may be greater than the width of the PCM layer 120. The floating spreader layer 130 may be positioned vertically above or below at least a portion of the heater line (e.g., heating portion 110c) and the PCM layer 120, such that the floating spreader layer 130 may dissipate heat from the PCM layer 120 and the heating portion 110c for purposes of transitioning the PCM layer 120 between an amorphous phase (i.e., the switch 100 is in an open state) and a crystalline phase (i.e., the switch 100 is in a closed state). Various shapes and dimensions of the floating spreader layer 130 that may induce varying heat dissipation amounts and times for purposes of transitioning between amorphous and crystalline phases are discussed herein.

Referring to FIGS. 4-6, the floating spreader layer 130 may have a rectangular shape of varying sizes (i.e., length “L”/distance between distal ends/sidewalls in the x-direction, width “W” between sidewalls in the y-direction, thickness in the z-direction). The center point C130 of the floating spreader layer 130 may be substantially aligned with the center point C110c of the heating portion 110c and the center point C120 of the PCM layer 120.

FIG. 4 illustrates a second alternative structure including a floating spreader layer 130 with sidewalls that are aligned or substantially aligned with outer peripheries of the signal contacts 150a, 150b. The floating spreader layer 130 as in FIG. 4 may therefore overlay or underlay a profile of components including at least the signal contacts 150a, 150b, the PCM layer 120, and at least a portion of the heater line (i.e., heating portion 110c). The floating spreader layer 130 may extend horizontally (i.e., in the x-direction) outward from vertical planes including sidewalls of the PCM layer 120. In other words, the floating spreader layer 130 may overlay or underlay a portion or all of the PCM layer 120, such that the floating spreader layer 130 has a larger width W and/or length L (i.e., in the y and x-directions) than the PCM layer 120. In some embodiments, the floating spreader layer 130 may have sidewalls 130-s1 and 130-s2 that overlap the heater line.

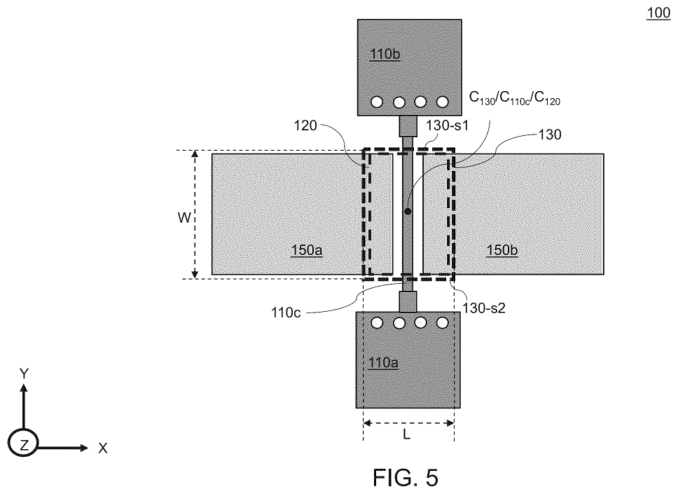

FIG. 5 illustrates a third alternative structure including a floating spreader layer 130 with sidewalls that are aligned or substantially aligned with outer peripheries of the PCM layer 120. The floating spreader layer 130 as in FIG. 5 may therefore overlay or underlay a profile of components including at least a portion of the signal contacts 150a, 150b, the PCM layer 120, and at least a portion of the heater line (i.e., heating portion 110c). The floating spreader layer 130 may include distal ends that are positioned vertically above or below (i.e., within same vertical planes) as distal sidewalls of the PCM layer 120. In other words, the floating spreader layer 130 may overlay or underlay a portion or all of the PCM layer 120, such that the floating spreader layer 130 has a same or substantially similar width W and/or length L (i.e., in the y and x-directions) as the PCM layer 120. In some embodiments, the floating spreader layer 130 may include sidewalls that are parallel to sidewalls of the PCM layer 120. In some embodiments, the floating spreader layer 130 may have sidewalls 130-s1 and 130-s2 that overlap the heater line.

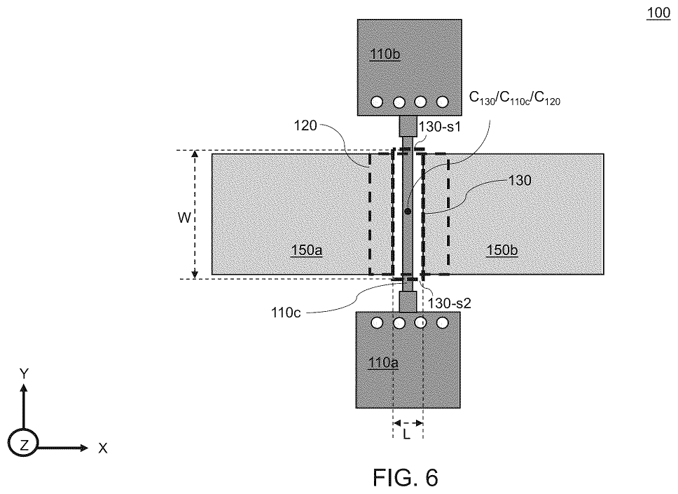

FIG. 6 illustrates a fourth alternative structure including a floating spreader layer 130 with sidewalls that are aligned or substantially aligned with inner peripheries of the signal contacts 150a, 150b. The floating spreader layer 130 as in FIG. 6 may therefore overlay or underlay a profile of components including at least a portion of the PCM layer 120 and at least a portion of the heater line (i.e., heating portion 110c). The floating spreader layer 130 may be positioned vertically between proximate sidewalls of the signal contacts 150a and 150b. In other words, the floating spreader layer 130 may overlay or underlay a portion of the PCM layer 120, such that the floating spreader layer 130 has a smaller width W and/or length L (i.e., in the y and x-directions) than the PCM layer 120. In some embodiments, the floating spreader layer 130 may have sidewalls 130-s1 and 130-s2 that overlap the heater line.

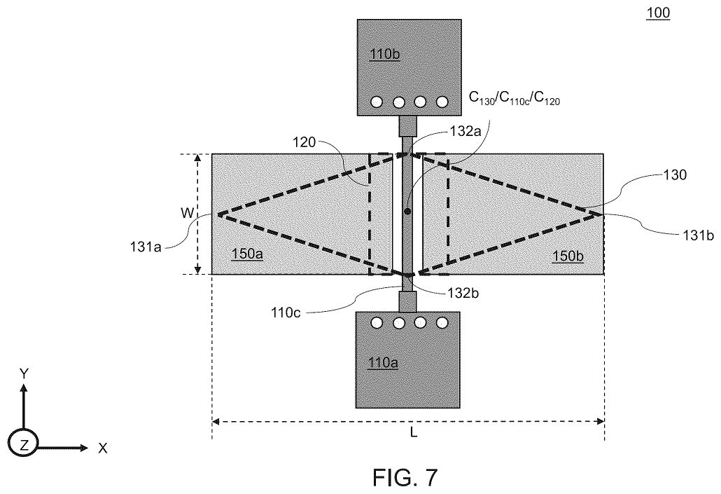

Referring to FIGS. 7-9, the floating spreader layer 130 may have a diamond shape of varying sizes (i.e., length L/distance between distal endpoints/corners in the x-direction, width W between middle corners/center points in the y-direction, thickness in the z-direction). The profile of the floating spreader layer 130 as illustrated in FIGS. 7-9 with respect to a top-down view may be formed in the shape of a diamond, rhombus, equilateral quadrilateral, or other form of parallelogram. The floating spreader layer 130 as illustrated in FIGS. 7-9 may include middle corners 132a, 132b positioned within a same vertical plane as the heater line (e.g., heating portion 110c), and may include distal endpoints 131a, 131b that are equidistant from the middle corners 132a, 132b. The floating spreader layers 130 may include middle corners 132a, 132b that may be positioned vertically above or below (i.e., within a same vertical plane) as the heater line (e.g., heating portion 110c), such that the center point C130 of the floating spreader layer 130 may be substantially aligned with the center point C110c of the heating portion 110c and the center point C120 of the PCM layer 120.

FIG. 7 illustrates a fifth alternative structure including a floating spreader layer 130 with angled sidewalls that are substantially within an outer periphery of the signal contacts 150a, 150b. The floating spreader layer 130 as in FIG. 7 may therefore overlay or underlay a profile of components including at least a portion of the signal contacts 150a, 150b, a portion of the PCM layer 120, and a portion of the heater line (i.e., heating portion 110c). The floating spreader layer 130 may extend horizontally (i.e., in the x-direction) outward from vertical planes including sidewalls of the PCM layer 120. In other words, the floating spreader layer 130 may overlay or underlay a portion of the PCM layer 120, such that the floating spreader layer 130 has a similar width W (i.e., distance between middle corner 132a and middle corner 132b in the y-direction) and/or larger length L (i.e., distance between distal endpoint 131a and distal endpoint 131b in the x-directions) than the PCM layer 120. The floating spreader layer 130 may include distal endpoints 131a, 131b that may be within a same vertical place as distal sidewalls of the signal contacts 150a, 150b.

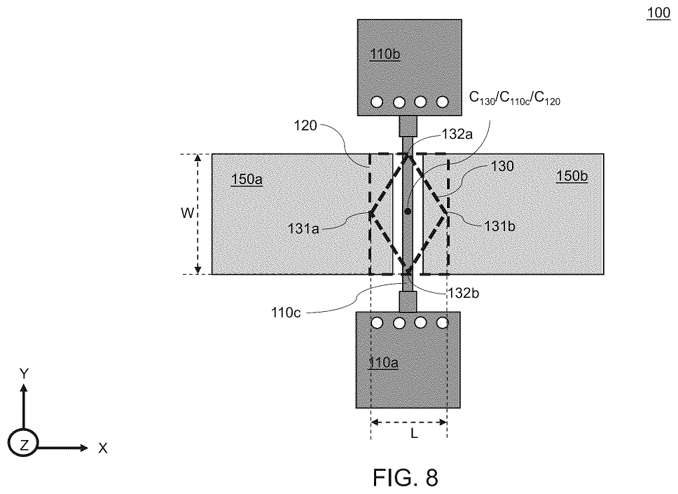

FIG. 8 illustrates a sixth alternative structure including a floating spreader layer 130 with angled sidewalls that are substantially within an outer periphery of the PCM layer 120. The floating spreader layer 130 as in FIG. 8 may therefore overlay or underlay a profile of components including at least a portion of the signal contacts 150a, 150b, a portion of the PCM layer 120, and a portion of the heater line (i.e., heating portion 110c). The floating spreader layer 130 may extend horizontally (i.e., in the x-direction) between vertical planes including sidewalls of the PCM layer 120. In other words, the floating spreader layer 130 may overlay or underlay a portion of the PCM layer 120, such that the floating spreader layer 130 has a same or substantially similar width W and/or length L (i.e., in the y and x-directions) as the PCM layer 120. The floating spreader layer 130 may include distal endpoints 131a, 131b that may be within a same vertical place as distal sidewalls of the PCM layer 120.

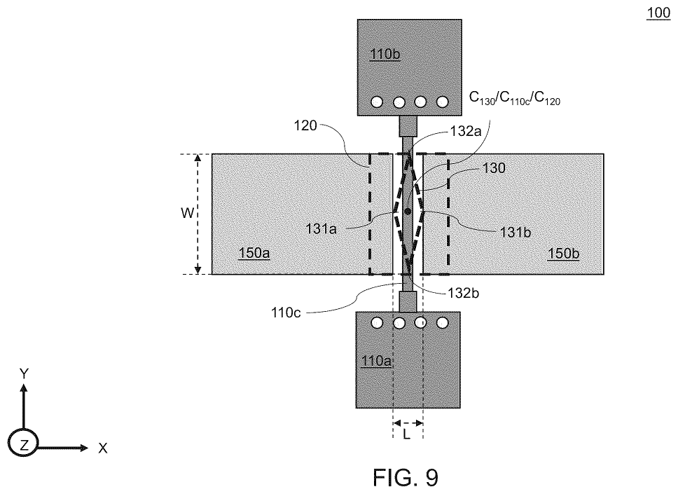

FIG. 9 illustrates a seventh alternative structure including a floating spreader layer 130 with angled sidewalls that are aligned or substantially aligned with inner peripheries of the signal contacts 150a, 150b. The floating spreader layer 130 as in FIG. 9 may therefore overlay or underlay a profile of components including at least a portion of the PCM layer 120 and a portion of the heater line (i.e., heating portion 110c). The floating spreader layer 130 may extend horizontally (i.e., in the x-direction) between vertical planes including proximate sidewalls of the signal contacts 150a, 150b. In other words, the floating spreader layer 130 may overlay or underlay a portion of the PCM layer 120, such that the floating spreader layer 130 has a similar width W (i.e., distance between middle corner 132a and middle corner 132b in the y-direction) and/or a smaller length L (i.e., distance between distal endpoint 131a and distal endpoint 131b in the x-directions) than the PCM layer 120. The floating spreader layer 130 may include distal endpoints 131a, 131b that may be within a same vertical place as proximate sidewalls of the signal contacts 150a, 150b.

The dimensions (width, length, thickness, shape/profile/footprint) of the floating spreader layer 130 may be any size, shape, or thickness that may be fine-tuned to adjust the heat dissipation (i.e., quenching) properties of the floating spreader layer 130 with respect to the PCM layer 120 while minimizing the power used to transition the phases of the PCM layer 120 for various chip package applications. For example, a larger floating spreader layer 130 may have better (i.e., faster) quenching capabilities to dissipate heat from the PCM layer 120 than a smaller floating spreader layer 130, and may therefore be faster at transitioning the PCM layer 120 form an amorphous phase to a crystalline phase. However, the larger floating spreader layer 130 may have poor thermal confinement which and may therefore increase the power required to then transition the PCM layer 120 back to an amorphous phase as compared to the smaller floating spreader layer 130. Thermal confinement may refer to the capabilities of a spreader to conduct heat from the PCM layer 120 and evenly (i.e., uniformly) spread (i.e., dissipate), the conducted heat across itself. A spreader with poor thermal confinement (i.e., uneven/nonuniform heat distribution), as exhibited in spreaders with large areas such as whole-area spreaders, may therefore cause overheating issues and may subsequently increase the power required to transition a PCM between phases.

Thus, a floating spreader layer 130 may be designed to have dimensions and materials that (i) minimize power used to transition the PCM layer 120 from an amorphous phase to a crystalline phase (i.e., good thermal confinement), (ii) maximize the amount of thermal energy/heat dissipation from the PCM layer 120 within a given period for transitioning from a crystalline phase to an amorphous phase (i.e., good thermal conduction), and/or (iii) minimize the transition times between amorphous and crystalline phases based on (i) and (ii). Therefore, dimensions of the floating spreader layer 130 may be based at least on application specific requirements including heat dissipation/quenching speed of the PCM layer 120 by the floating spreader layer 130, available system power for transitioning the PCM layer 120, minimum power required to transition the PCM layer 120, and a PCM layer 120 maximum temperature and heat profile (i.e., exceeding said profile may damage PCM layer 120)). The dimensions of the floating spreader layer 130 may further be based at least on dimensions including widths, lengths, thickness, and profiles/shapes of the heater contacts 110a, 110b, 110c, PCM layer 120, and signal contacts 150a, 150b.

Thus, examples of the floating spreader layer 130 as shown in and described with reference to FIGS. 4-9 are merely illustrative, and are not meant to limit the various shapes and sizes of the floating spreader layer 130. For example, a floating spreader layer 130 may be larger in an application including a PCM layer 120 with a larger width than a floating spreader layer 130 in an application including a PCM layer 120 with a smaller comparative width. As another example, floating spreader layers 130 in applications may vary for PCM layers 120 comprising different materials. The floating spreader layer 130 may therefore have dimensions other than those illustrated in FIGS. 4-9. For example, a floating spreader layer 130 may have dimensions anywhere in between the dimensions as illustrated in FIGS. 4 and 6, or as illustrated in FIGS. 7 and 9. As another example, the floating spreader layer 130 may have extend over the heating contacts 110a, 110b, such that the width W of the floating spreader layer 130 is larger than the width of the PCM layer 120. As a further example, the floating spreader layer 130 may have a length L of any size, such as a length extending beyond distal sidewalls of the signal contacts 150a, 150b.

In some embodiments, the floating spreader layer 130 may have varying thicknesses in the z-direction across the profile of the floating spreader layer 130 with respect to the x-direction and y-direction. For example, the floating spreader layer 130 may have a thickness towards the center point C130 that is greater than a thickness or thicknesses towards outer edges of the floating spreader layer 130. As another example, the floating spreader layer 130 may have a thickness towards the center point C130 that is less than a thickness or thicknesses towards outer edges of the floating spreader layer 130.

A floating spreader layer 130 with a diamond, or rhombus, shape (e.g., as illustrated in FIGS. 7-9) may further improve upon PCM layer 120 power reduction and quenching performance as compared to a floating spreader layer 130 with a rectangular shape. With respect to component reliability, a floating spreader layer 130 with a diamond shape having a width W and length L may have better power reduction for transitioning the PCM layer 120 from an amorphous phase to a crystalline phase (i.e., better thermal confinement), faster quenching/heat dissipation from the PCM layer 120 for transitioning from a crystalline phase to an amorphous phase (i.e., better thermal conduction), and better uniformity to minimize overheating risk as compared to a floating spreader layer 130 with a rectangular shape. The benefits of the diamond-shaped floating spreader layer 130 may be achieved due to its diamond-shape profile, which more closely resembles a heat distribution pattern radiating from the PCM layers 120 and the heating portion 110c.

FIGS. 10-16 are various vertical cross-sectional views of alternate structures including a floating spreader layer 130 according to some embodiments of the present disclosure. The alternate structures illustrated include various configurations in which one or more floating spreader layers (e.g., 130, 132, 135, 136) are formed to be positioned vertically beneath and/or vertically above the heating portion 110c and the PCM layer 120.

FIG. 10 illustrates a vertical cross-sectional view of an eighth alternative structure including a bottom floating spreader 130 and a top floating spreader layer 132 according to some embodiments of the present disclosure. In addition to a floating spreader layer 130 formed beneath the heating portion 110c and the PCM layer 120, a second additional floating spreader layer may be formed above the heating portion 110c and the PCM layer 120, which may be referred to as a top floating spreader layer 132. The bottom floating spreader layer 130 and the top floating spreader layer 132 may be formed to have dimensions such that the bottom floating spreader layer 130 and the top floating spreader layer 132 simultaneously function to maximize thermal confinement for power reduction purposes and to maximize thermal reduction for quenching purposes within the switch 100. The top floating spreader layer 132 may be formed in a similar as and may function similarly to the floating spreader layer 130 as described above.

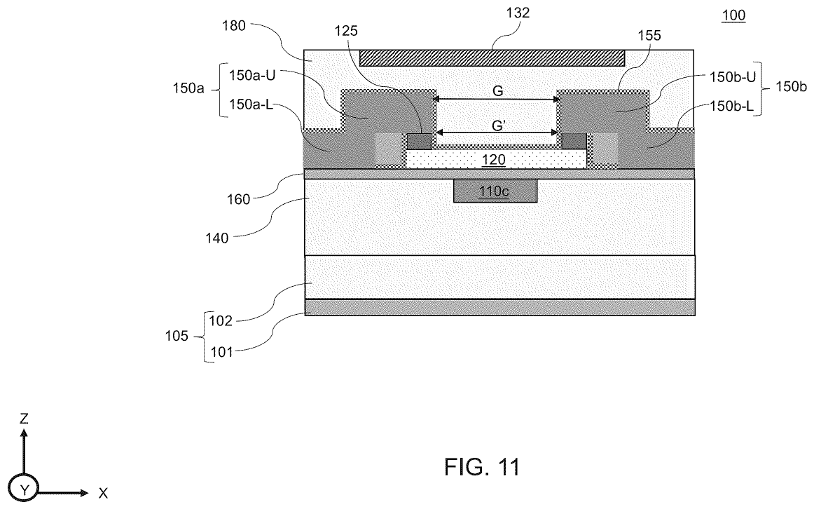

FIG. 11 illustrates a vertical cross-sectional view of a ninth alternative structure including a top floating spreader layer 132 according to some embodiments of the present disclosure. A floating spreader layer may be formed above the heating portion 110c and the PCM layer 120, which may be referred to as a top floating spreader layer 132. The top floating spreader layer 132 may be formed to have dimensions such that the top floating spreader layer 132 functions to maximize thermal confinement for power reduction purposes and to maximize thermal reduction for quenching purposes within the switch 100. The top floating spreader layer 132 may be formed in a similar as and may function similarly to the floating spreader layer 130 as described above.

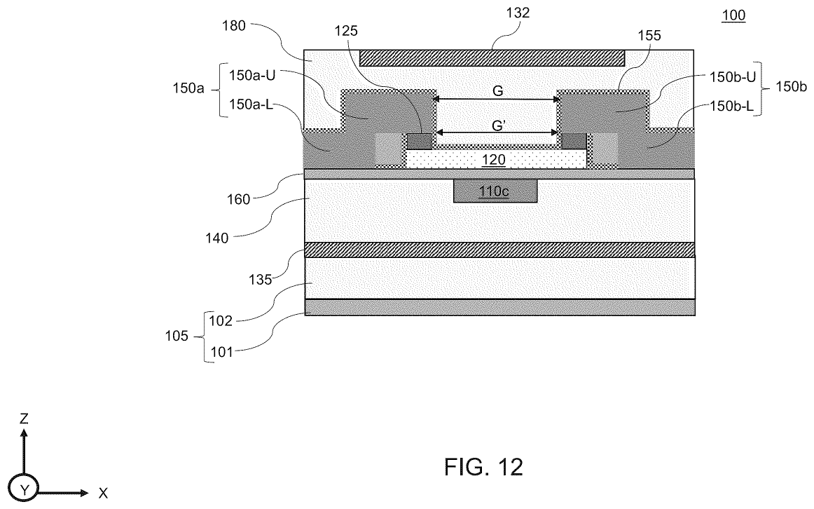

FIG. 12 illustrates a vertical cross-sectional view of a tenth alternative structure including a bottom whole-area spreader layer 135 and a top floating spreader layer 132 according to some embodiments of the present disclosure. A bottom whole-area spreader layer 135 may be formed beneath the heating portion 110c and the PCM layer 120, and a top floating spreader layer 132 may be formed above the heating portion 110c and the PCM layer 120. The top floating spreader layer 132 may be formed to have dimensions such that the bottom whole-area spreader layer 135 and the top floating spreader layer 132 simultaneously function to maximize thermal confinement for power reduction purposes and to maximize thermal reduction for quenching purposes within the switch 100. The top floating spreader layer 132 may be formed in a similar as and may function similarly to the floating spreader layer 130 as described above.

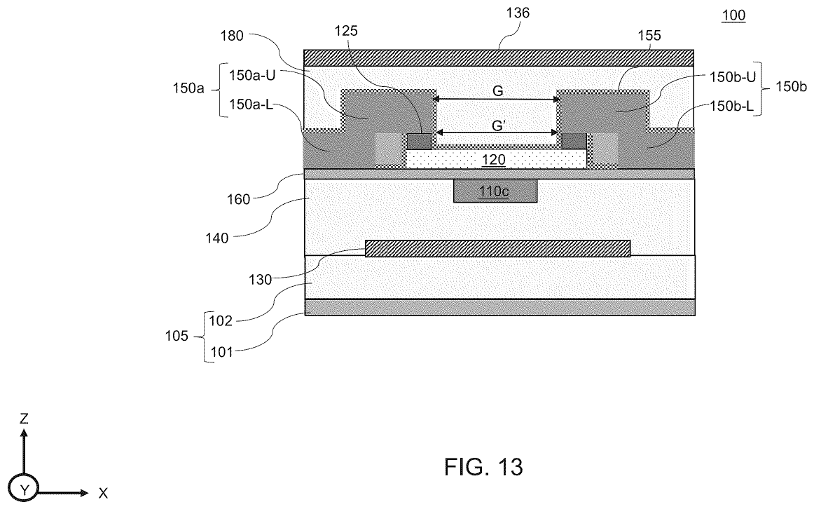

FIG. 13 illustrates a vertical cross-sectional view of an eleventh alternative structure including a top whole-area spreader layer 136 and a bottom floating spreader 130 according to some embodiments of the present disclosure. A top whole-area spreader layer 136 may be formed above the heating portion 110c and the PCM layer 120, and a bottom floating spreader layer 130 may be formed beneath the heating portion 110c and the PCM layer 120. The bottom floating spreader layer 130 may be formed to have dimensions such that the top whole-area spreader layer 136 and the bottom floating spreader layer 130 simultaneously function to maximize thermal confinement for power reduction purposes and to maximize thermal reduction for quenching purposes within the switch 100.

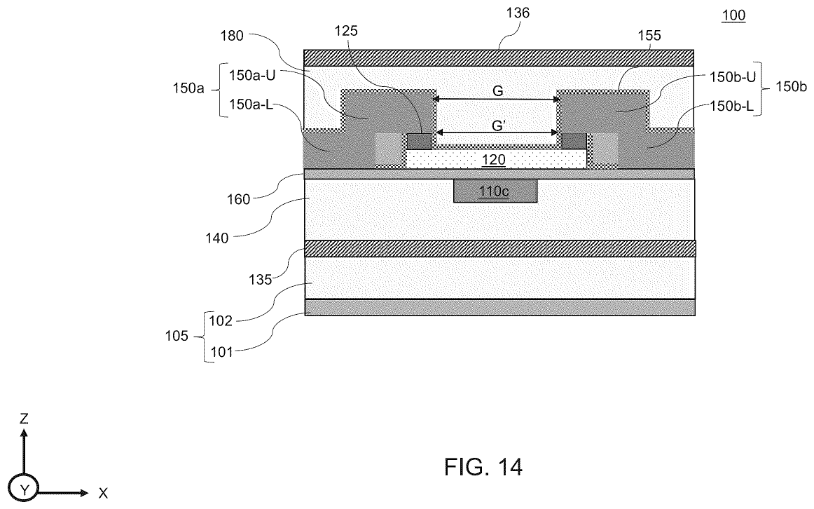

FIG. 14 illustrates a vertical cross-sectional view of a twelfth alternative structure including a top whole-area spreader layer 136 and a bottom whole-area spreader layer 135 according to some embodiments of the present disclosure. A top whole-area spreader layer 136 may be formed above the heating portion 110c and the PCM layer 120, and a bottom whole-area spreader layer 135 may be formed beneath the heating portion 110c and the PCM layer 120. The top whole-area spreader layer 136 and the bottom whole-area spreader layer 135 may simultaneously function to maximize thermal confinement for power reduction purposes and to maximize thermal reduction for quenching purposes within the switch 100.

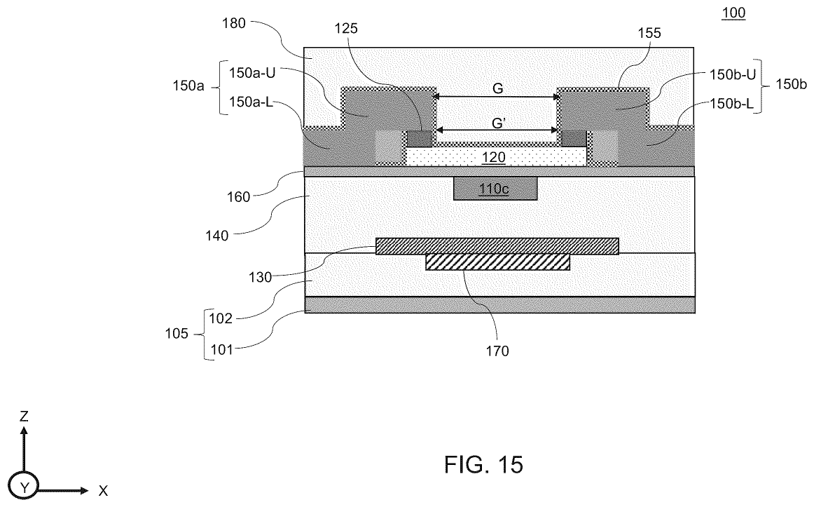

FIG. 15 illustrates a vertical cross-sectional view of a thirteenth alternative structure including a floating spreader layer 130 and a copper floating spreader layer 170 according to some embodiments of the present disclosure. A copper floating spreader layer 170 may be formed in a similar manner as the floating spreader layer 130. The copper floating spreader layer 170 may be implemented within a switch 100 to further improve thermal confinement for power reduction purposes and thermal reduction for quenching purposes beyond the capabilities of the floating spreader layer 130. The copper floating spreader layer 170 may further improve uniformity of the temperature profile of the PCM layer 120 to increase switch 100 reliability.

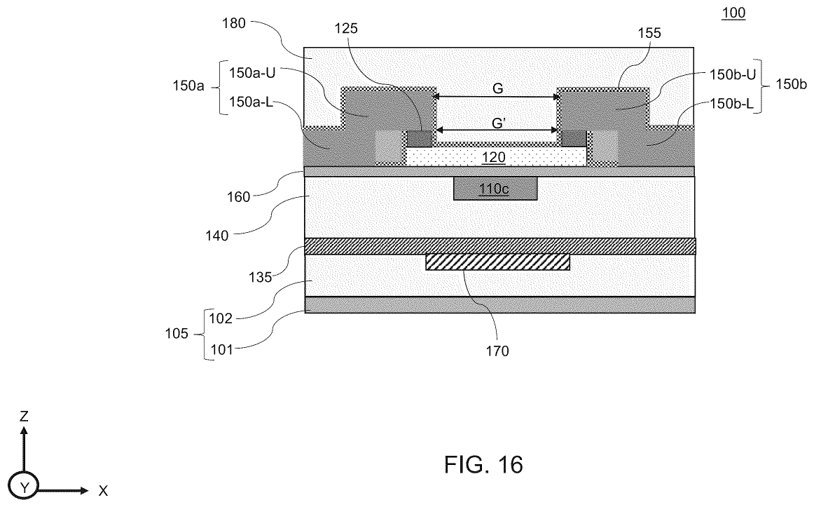

FIG. 16 illustrates a vertical cross-sectional view of a fourteenth alternative structure including a bottom whole-area spreader layer 135 and a copper floating spreader layer 170 according to some embodiments of the present disclosure. A copper floating spreader layer 170 may be formed in a similar manner as the bottom whole-area spreader layer 135 or a floating spreader layer 130 having a specific shape (i.e., not a whole-area spreader). The copper floating spreader layer 170 may be implemented within a switch 100 to further improve thermal confinement for power reduction purposes and thermal reduction for quenching purposes beyond the capabilities of the bottom whole-area spreader layer 135. The copper floating spreader layer 170 may further improve uniformity of the temperature profile of the PCM layer 120 to increase switch 100 reliability.

As illustrated, the copper floating spreader layer 170 may be formed, and the bottom whole-area spreader layer 135 may be formed on top of the copper floating spreader layer 170, such that a bottom surface of the bottom whole-area spreader layer 135 is in contact with a top surface of the copper floating spreader layer 170. In some embodiments, the copper floating spreader layer 170 may be formed to be positioned vertically between the heater portion 110c and the bottom whole-area spreader layer 135. For example, the copper floating spreader layer 170 may be formed on top of the bottom whole-area spreader layer 135, such that a bottom surface of the copper floating spreader layer 170 is in contact with a top surface of the bottom whole-area spreader layer 135. Similarly, in some embodiments, the copper floating spreader layer 170 may be implemented in structures such as those illustrated in FIGS. 10-15. For example, the copper floating spreader layer 170 may be positioned beneath and have a top surface in contact with a bottom surface of the bottom floating spreader layer 130, the top floating spreader layer 132, the bottom whole-area spreader layer 135, and/or the top whole-area spreader layer 136. As another example, the copper floating spreader layer 170 may be positioned above and have a bottom surface in contact with a top surface of the bottom floating spreader layer 130, the top floating spreader layer 132, the bottom whole-area spreader layer 135, and/or the top whole-area spreader layer 136. In some embodiments, multiple copper floating spreader layers 170 may be implemented within a single switch 100.

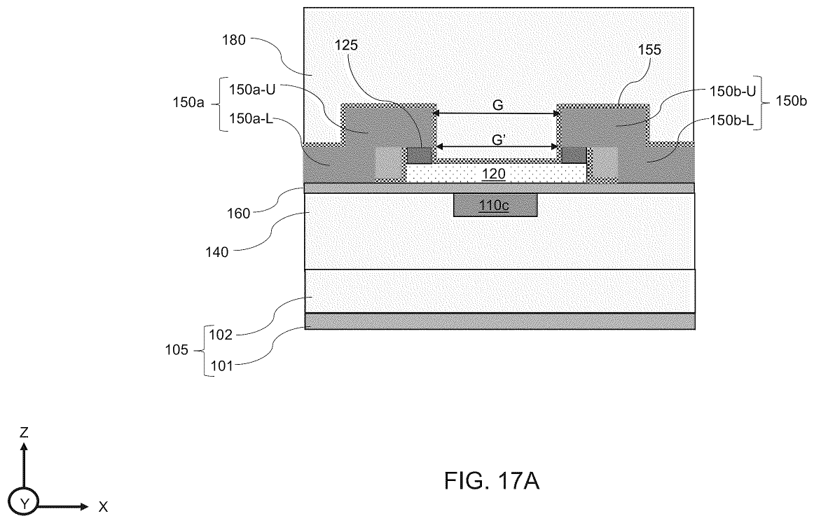

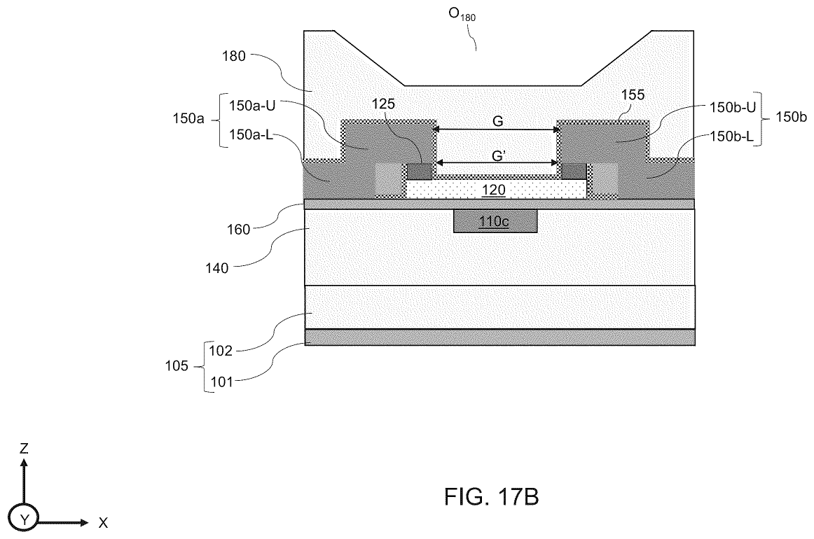

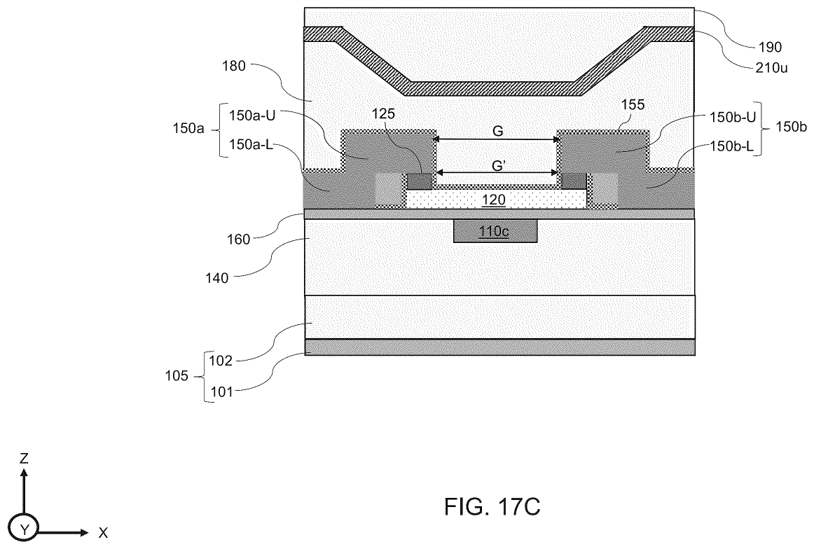

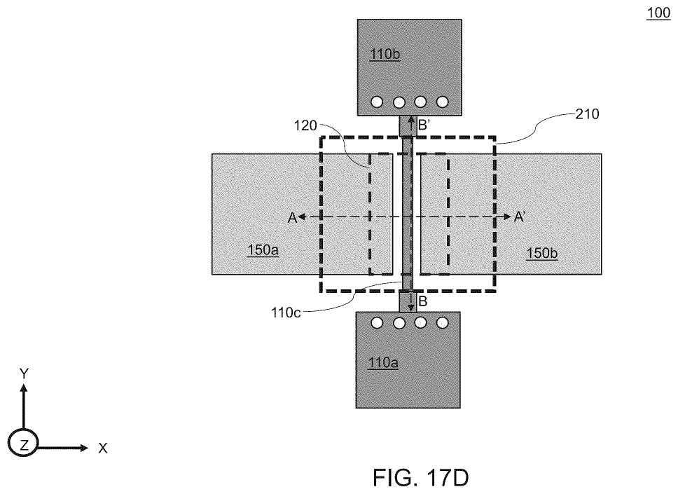

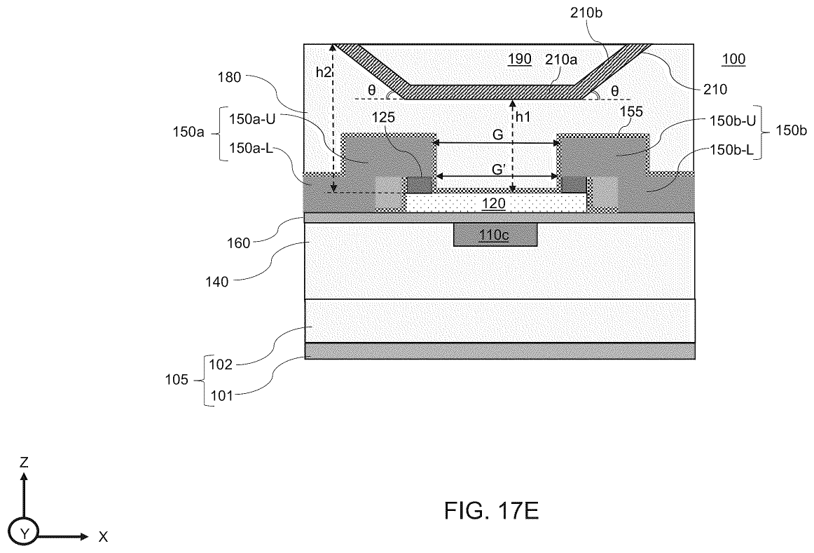

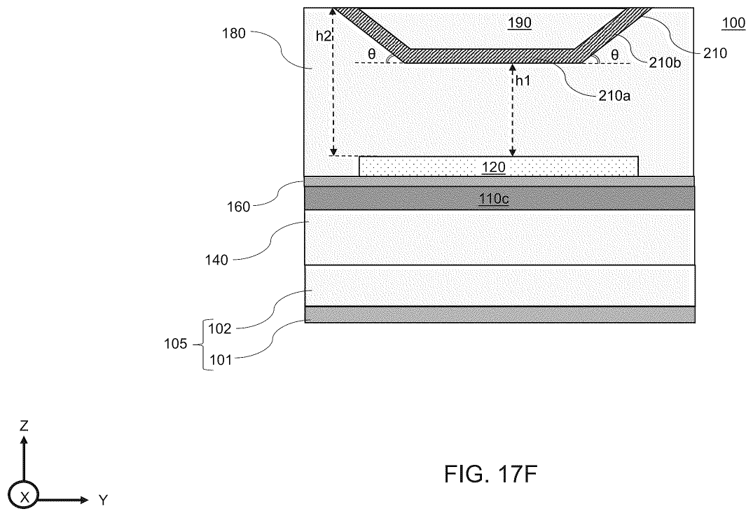

FIGS. 17A-17F illustrate various views of forming a fifteenth alternative structure including a U-shaped floating spreader layer 210 according to some embodiments of the present disclosure.

FIG. 17A illustrates a vertical cross-sectional view of an intermediate structure including forming an insulating layer 180 according to some embodiments of the present disclosure. The insulating layer 180 may have a structure (e.g., thickness, materials) similar to the structure as the upper substrate layer 102. As illustrated in FIG. 17A, the insulating layer 180 may be formed on a top surface of the contact protective layer 155 and around sidewalls of the contact protective layer 155. A thickness of the insulating layer 180 measured from the surface of the thermal dielectric layer 160 may be equal to or greater than a combined thickness of the signal contact 150a (or signal contact 150b) and the contact protective layer 155. In at least one embodiment, the thickness of the insulating layer 180 may be at least twice the combined thickness of the signal contact 150a and the contact protective layer 155. The insulating layer 180 may be formed, for example, by thin film creation such as by chemical vapor deposition (CVD), plasma-enhanced CVD (PECVD), low pressure chemical vapor deposition (LPCVD), physical vapor deposition (PVD) (e.g., sputtering) or atomic layer deposition (ALD).

FIG. 17B is a vertical cross-sectional view of an intermediate structure including an opening O180 in the insulating layer 180 according to some embodiments of the present disclosure. The opening O180 (e.g., U-shaped floating spreader layer trench) may be formed in the upper surface of the insulating layer 180. The opening O180 may be formed in substantially the same location (e.g., a central portion of the insulating layer 180) and have substantially the same design as the subsequently-formed U-shaped floating spreader layer 210. The opening O180 may extend across a portion of the insulating layer 180 in both the x-direction and y-direction. A depth of the opening O180 in the z-direction may be less than a thickness of the insulating layer 180. In at least one embodiment, the depth of the opening O180 may be substantially the same as the of the subsequently-formed U-shaped floating spreader layer 210. The opening O180 may be etched to create a well, or U-shaped cavity, within the insulating layer 180, such that the opening O180 extends downward into the insulating layer 180 to form a cavity having dimensions defined by angled sidewalls of the etched insulating layer 180.

The opening O180 may be formed in the insulating layer 180 by etching. The etching may be performed, for example, by a photolithographic process. The photolithographic process may include forming a patterned photoresist mask (not shown) on the insulating layer 180 so that an upper surface of the insulating layer 180 is exposed through openings in the photoresist mask. Then, the exposed upper surface of the insulating layer 180 may be etched (e.g., by wet etching, dry etching, etc.) through the openings in the photoresist mask. The photoresist mask may be subsequently removed by ashing, dissolving the photoresist mask or by consuming the photoresist mask during the etch process.

FIG. 17C is a vertical cross-sectional view of an intermediate structure including an unetched U-shaped floating spreader layer 210u according to some embodiments of the present disclosure. The unetched U-shaped floating spreader layer 210u may be formed on the surface of the insulating layer 180 within the opening O180. Depositing the unetched U-shaped floating spreader layer 210u conformally on a top surface of the insulating layer 180 may form a well that substantially conforms to the boundaries of the well-shaped opening O180. To form the unetched U-shaped floating spreader layer 210u, a layer of thermally conductive material (e.g., a compound such as SiC and/or metal such as copper, and/or other thermally conductive materials or metals with a thermal conductivity greater than 100 W/mK) may be formed on the surface of the insulating layer 180. The layer of thermally conductive material may be deposited to have a thickness in a range from 0.05 μm to about 1 μm. The layer of thermally conductive material may be formed, for example, by thin film creation such as by chemical vapor deposition (CVD), plasma-enhanced CVD (PECVD), low pressure chemical vapor deposition (LPCVD), physical vapor deposition (PVD) (e.g., sputtering) or atomic layer deposition (ALD).

After depositing the unetched U-shaped floating spreader layer 210u, an insulating layer 190 may be formed on a top surface of the unetched U-shaped floating spreader layer 210u. The insulating layer 190 may be formed, for example, by thin film creation such as by chemical vapor deposition (CVD), plasma-enhanced CVD (PECVD), low pressure chemical vapor deposition (LPCVD), physical vapor deposition (PVD) (e.g., sputtering) or atomic layer deposition (ALD).

FIGS. 17D-17F are various views of the fifteenth alternative structure after etching unetched U-shaped floating spreader layer 210u to form a U-shaped floating spreader layer 210 according to an embodiment of the present disclosure. FIG. 17D is a top-down perspective view of the fifteenth alternative structure, in which various layers (e.g., 105, 140, 160, 180, 190) are not shown for ease of illustrating the U-shaped floating spreader layer 210 with respect to the heating portion 110c, the PCM layer 120, and the signal contacts 150a, 150b. FIG. 17E is a vertical cross-sectional view along the horizontal plane A-A′ of FIG. 17D according to an embodiment of the present disclosure. FIG. 17F is a vertical cross-sectional view along the horizontal plane B-B′ of FIG. 17D according to an embodiment of the present disclosure.

A top portion of the insulating layer 190 and peripheral portions of the unetched U-shaped floating spreader layer 210u may be etched to form the U-shaped floating spreader layer 210. The etching process may be performed to remove peripheral portions of the unetched U-shaped floating spreader layer 210u that extend beyond outer boundaries of the previously-filled opening O180. Thus, an outer periphery of the U-shaped floating spreader layer 210 may be defined by an outer periphery of the U-shaped floating spreader layer 210, in addition to an etch depth of the process used to etch the outer portions of the unetched U-shaped floating spreader layer 210u. In some embodiments, the U-shaped floating spreader layer 210 may be formed by using a planarization process, such as a CMP. The unetched U-shaped floating spreader layer 210u and insulating layer 190 may be planarized by the CMP process.

The U-shaped floating spreader layer 210 may include a first portion 210a (e.g., a flat portion) and an angled portion 210b that extends outward from the first portion 210a at a tapered angle θ, in which a peripheral of the angled portion 210b is a greater vertical distance h2 from the PCM layer 120 than the first portion 210a. For example, a bottom surface of the first portion 210a of the U-shaped floating spreader layer 210 may be a distance h1 in the z-direction from a top surface of the PCM layer 120, and an outer periphery of the angled portion 210b may be a distance h2 in the z-direction from a horizontal plane including a top surface of the PCM layer 120. In some embodiments, the angled portion 210b may extend beyond a vertical plane including a periphery of the PCM layer 120. In some embodiments, the distance h1, distance h2, and tapered angle θ may be defined by the etching process to form the opening O180. In some embodiments, the distance h2 may be greater than the distance h1, such that the angled portion 210b fans upwards from the first portion 210a and away from the PCM layer 120. In some embodiments, the distance h2 may be less than the distance h1, such that the angled portion fans downwards towards the PCM layers 120. The tapered angle θ may be any angle value, such as in a range of angles from 20 degrees to 60 degrees.

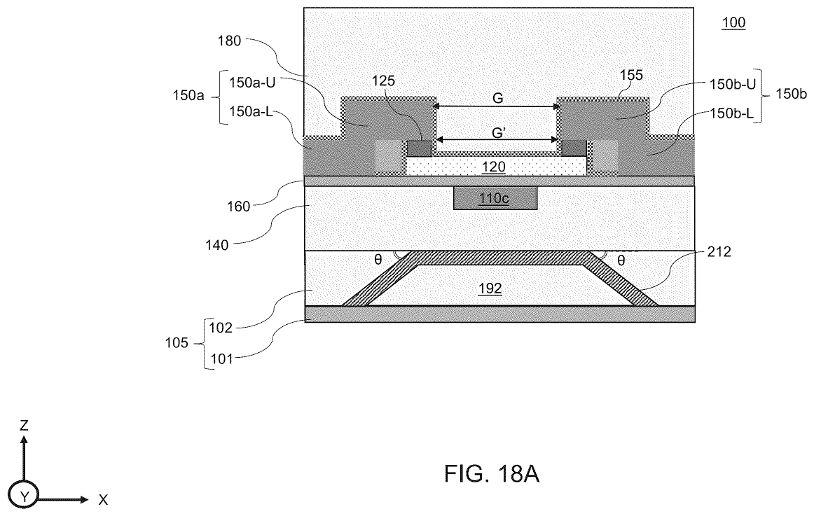

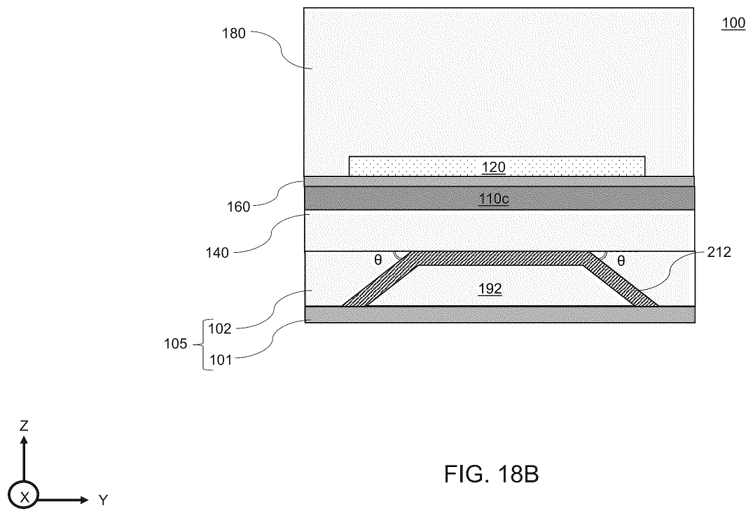

FIGS. 18A and 18B are various views of a sixteenth alternative structure including a reversed U-shaped floating spreader layer 212 according to an embodiment of the present disclosure. FIG. 18A is a vertical cross-sectional view along the horizontal plane A-A′ of FIG. 17D according to an embodiment of the present disclosure. FIG. 18B is a vertical cross-sectional view along the horizontal plane B-B′ of FIG. 17D according to an embodiment of the present disclosure. The reversed U-shaped floating spreader layer 212 may be formed in a similar manner as the floating spreader layer 130 and the U-shaped floating spreader layer 210, such that the reversed U-shaped floating spreader layer 212 may be formed by combining some or all of the portions of the processes used to form floating spreader layer 130 and the U-shaped floating spreader layer 210. The reversed U-shaped floating spreader layer 212 may be formed over an insulating layer 192. The insulating layer 192 may be etched to form a mound (as illustrated) upon which the reversed U-shaped floating spreader layer 212 may be deposited and formed to create the tapered angle θ. In some embodiments, both a U-shaped floating spreader layer 210 and a reversed U-shaped floating spreader layer 212 may be implemented within a single switch 100.

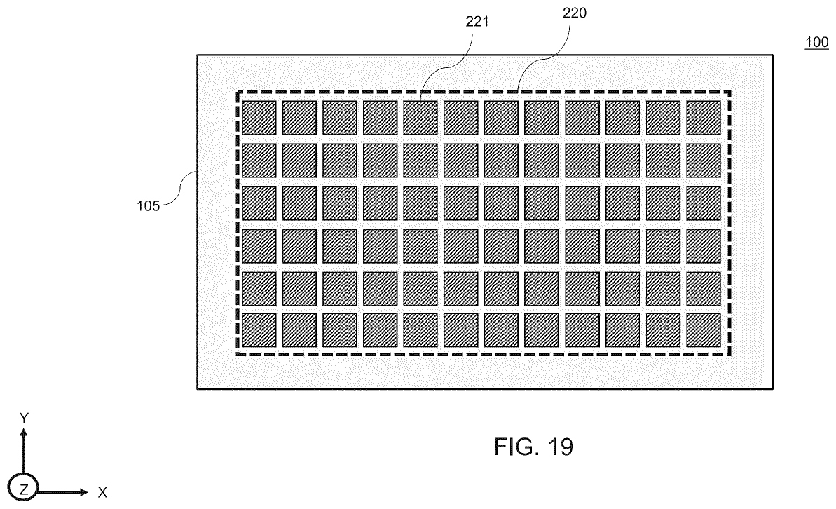

FIG. 19 is a seventeenth alternative structure including a patterned rectangular floating spreader layer 220 according to an embodiment of the present disclosure. For ease of illustration, the patterned rectangular floating spreader layer 220 is shown as being etched after depositing a thermally conductive material according to the processes described with reference to FIG. 2B. With reference to FIG. 19, the patterned rectangular floating spreader layer 220 is illustrated as a dashed line encompassing any number of etched portions 221.

The layer of thermally conductive material may then be patterned to have a desired metal pattern and shape according to the various embodiments described herein. The thermally conductive material may be patterned by etching. The etching may be performed, for example, by a photolithographic process that may include forming a patterned photoresist mask (not shown) on the layer of thermally conductive material so that an upper surface of the layer of thermally conductive material is exposed through openings in the photoresist mask. Then, the exposed upper surface of the layer of thermally conductive material may be etched (e.g., by wet etching, dry etching, etc.) through the openings in the photoresist mask. The photoresist mask may be subsequently removed by ashing, dissolving the photoresist mask or by consuming the photoresist mask during the etch process.

The etched portions 221 may be electrically isolated from each other, and may be of any size (width and length), shape, or thickness. The etched portions 221 may be formed to have any amount of space between other etched portions 221 within the array of etched portions 221. The etched portions 221 may be etched to create any size array within the patterned rectangular floating spreader layer 220. For example, an array of 6 etched portions 221 by 12 etched portions 221 is illustrated, but any other array size may be implemented within the patterned rectangular floating spreader layer 220. The dimensions of the etched portions 221 and the array size of the patterned rectangular floating spreader layer 220 may be formed to further fine tune maximization of thermal confinement for power reduction purposes and of thermal reduction for quenching purposes within the switch 100. The patterned rectangular floating spreader layer 220 may be implemented in various embodiments, including embodiments including a floating spreader layer (e.g., 130, 132, 135, 136, 210, 212).

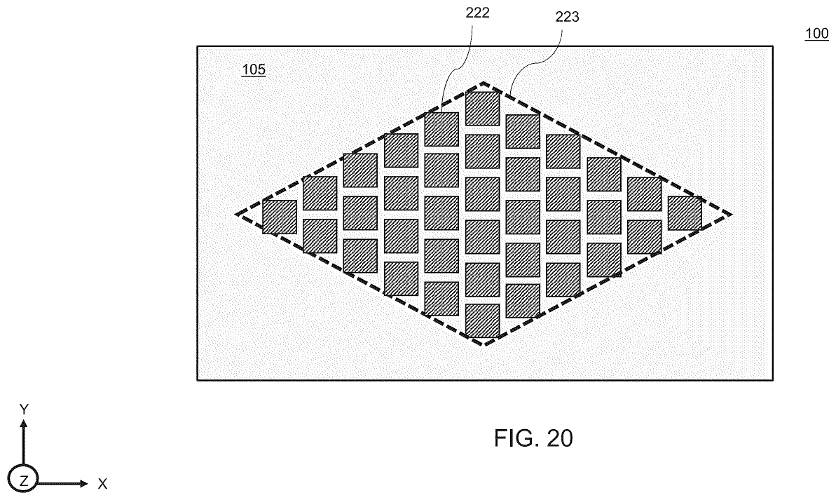

FIG. 20 is an eighteenth alternative structure including a patterned diamond floating spreader layer 222 according to an embodiment of the present disclosure. The patterned diamond floating spreader layer 222 may include etched portions 223 and may be formed in a similar manner as the patterned rectangular floating spreader layer 220. The patterned diamond floating spreader layer 222 may include any size array of etched portions 223, and the etched portions 221 may be of any size (width and length), shape, or thickness.

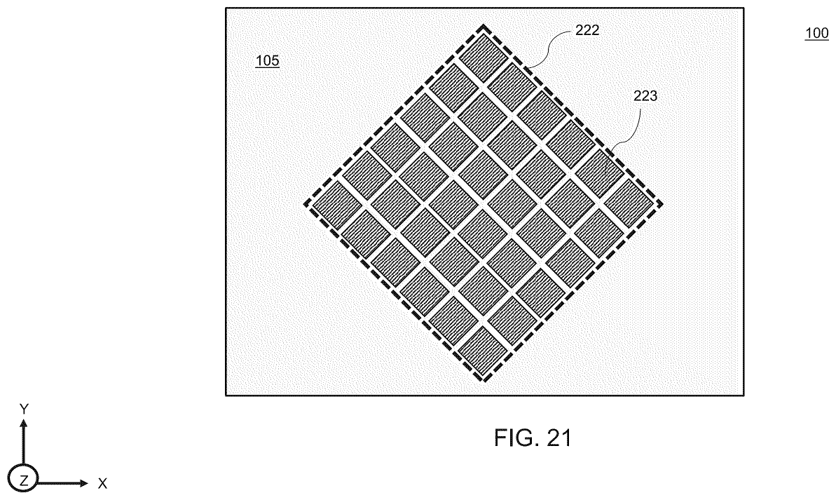

FIG. 21 is a nineteenth alternative structure including a patterned diamond floating spreader layer 222 according to an embodiment of the present disclosure. The patterned diamond floating spreader layer 222 may include etched portions 223 and may be formed in a similar manner as the patterned rectangular floating spreader layer 220 and the patterned diamond floating spreader layer 222. The patterned diamond floating spreader layer 222 may include any size array of etched portions 223, and the etched portions 223 may be of any size (width and length), shape, or thickness.

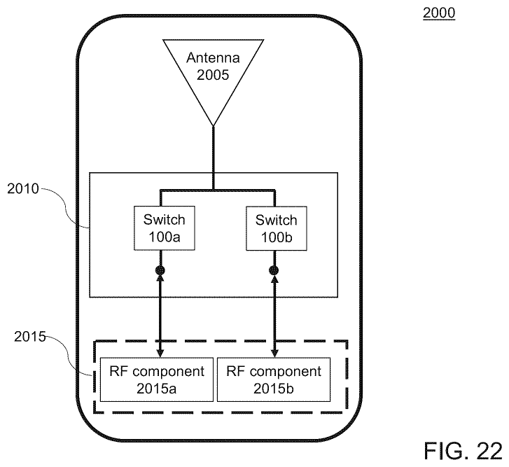

FIG. 22 illustrates an exemplary block diagram of a Radio Frequency (RF) transceiver system 2000, in accordance with some embodiments of the present disclosure. The transceiver system 2000 may be included, for example, in a communication device such as a mobile phone (e.g., cellular phone). As illustrated in FIG. 22, the RF transceiver system 2000 may include one or more antennas 2005 such as a main antenna, diversity antenna, etc. The RF transceiver system 2000 may also include a switch module 2010 (e.g., RF switch module). The switch module 2010 may include one or more switches 100. The RF transceiver system 2000 may also include an RF component section 2015. The RF component section 2015 may include a plurality of RF components 2015a, 2015b, etc. The RF components 2015a, 2015b may include, for example, a filter such as a receiver (Rx) filter or low-pass filter (LPF), and/or other types of RF components. The RF components 2015a, 2015b may be connected to other components within the RF transceiver system 2000. For example, in at least one embodiment, one or more of the RF components 2015a, 2015b may include an Rx filter connected to a transceiver processor. The transceiver processor may include, for example, a low noise amplifier, an RF filter, a mixer, a demodulator, a digital-to-analog converter, an analog-to-digital converter, a modulator, etc.) In at least one embodiment, one or more of the RF components 2015a, 2015b may include an LPF connected to a power amplifier (PA) module which is connected to the transceiver processor.

In operation, the switch module 2010 may have a first configuration in which a PCM layer 120 of the switch 100a is in a crystalline phase so that the switch 100a is a closed state, and a PCM layer 120 of the switch 100b is in an amorphous phase so that the switch 100b is in an open state. In the first configuration, the switch module 2010 may direct a signal (e.g., RF signal) from the antenna 2005 to the RF component 2015a (e.g., Rx filter).

The switch module 2010 may also have a second configuration in which the PCM layer 120 of the switch 100a is in an amorphous phase so that the switch 100a is in an open state, and the PCM layer 120 of the switch 100b is in a crystalline phase so that the switch 100b is a closed state. In the second configuration, the switch module 2010 may direct a signal (e.g., RF signal) from the RF component 2015b (e.g., LPF) to the antenna 2005.

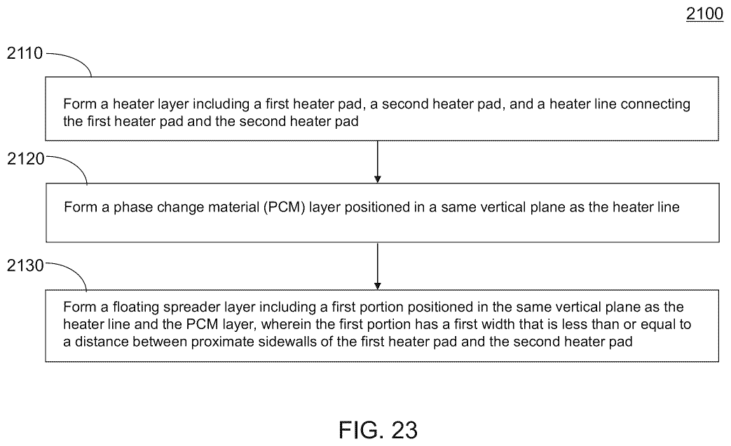

Referring to FIG. 23, a flowchart illustrates a method 2100 including steps for forming a switch structure according to an embodiment of the present disclosure.

Referring to step 2110 and FIGS. 2D-2F, a heater layer (110a, 110b, 110c) including a first heater pad (e.g., 110a, 110b), a second heater pad (e.g., 110a, 110b), and a heater line (e.g., heater portion 110c) connecting the first heater pad and the second heater pad may be formed.

Referring to step 2120 and FIGS. 2G and 2H, a PCM layer 120 positioned in a same vertical plane as the heater line (e.g., heater portion 110c) may be formed.

Referring to step 2130 and FIGS. 2B and 4-21, a floating spreader layer (e.g., 130, 132, 135, 136, 210, 212, 220, 222) including a first portion (e.g., 210a) positioned in the same vertical plane as the heater line (e.g., heater portion 110c) and the PCM layer 120 may be formed. In some embodiments, the floating spreader layer 130 may have at least one sidewall (e.g., 130-s1, 130-s2, middle corners 132a, 132b) overlapping the heater line (e.g., heater portion 110c).

The order of operations of the steps 2110, 2120, and 2130 are merely illustrative and are not meant to be limiting. For example, the steps 2110, 2120, and 2130 may be performed in any order (e.g., 2110, 2120, then 2130; 2120, 2110, then 2130; 2130, 2110, then 2120; 2130, 2120, then 2110) depending on a desired configuration of the switch 100. In some embodiments, the floating spreader layer (e.g., 130, 132, 135, 136, 210, 212, 220, 222) may be formed prior to forming the heater layer (110a, 110b, 110c) and the PCM layer 120 as described in steps 2110 and 2120, such that the floating spreader layer is positioned vertically beneath the PCM layer 120 and the heater layer (110a, 110b, 110c). In some embodiments, the floating spreader layer may be formed after forming the heater layer (110a, 110b, 110c) and the PCM layer 120 as described in steps 2110 and 2120, such that the floating spreader layer is positioned vertically above the PCM layer 120 and the heater layer (110a, 110b, 110c). In some embodiments, the heater layer (110a, 110b, 110c) may be formed prior to forming the PCM layer 120, such that the heater layer (110a, 110b, 110c) is positioned vertically beneath the PCM layer 120. In some embodiments, the heater layer (110a, 110b, 110c) may be formed after forming the PCM layer 120, such that the heater layer (110a, 110b, 110c) is positioned vertically above the PCM layer 120.

In some embodiments, forming the floating spreader layer (e.g., 130, 132, 135, 136, 210, 212, 220, 222) positioned in the same vertical plane as the heater line (e.g., heater portion 110c) and the PCM layer 120 may further include forming the floating spreader layer in a diamond shape including middle corners (132a, 132b) and distal endpoints (131a, 131b) with respect to a top-down view, in which the middle corners are positioned in a same vertical plane as the heater line, and the distal endpoints are equidistant from the middle corners.

In some embodiments, forming the floating spreader layer (e.g., 130, 132, 135, 136, 210, 212, 220, 222) positioned in the same vertical plane as the heater line (e.g., heater portion 110c) and the PCM layer 120 may further include forming the floating spreader layer to include an angled portion 210b that extends outward from the first portion at a tapered angle, in which a vertical distance between a periphery of the angled portion 210b and a horizontal plane including a top surface of the PCM layer 120 is greater than a distance between a bottom surface of the first portion 210a and the top surface of the PCM layer 120.

In some embodiments, forming the floating spreader layer (e.g., 130, 132, 135, 136, 210, 212, 220, 222) positioned in the same vertical plane as the heater line (e.g., heater portion 110c) and the PCM layer 120 may further include forming the floating spreader layer to include at least two electrically isolated portions (e.g., 221, 223).

In some embodiments, the method 2100 may further include forming a copper floating spreader layer 170 to be in contact with a surface of the floating spreader layer (e.g., 130, 132, 135, 136, 210, 212, 220, 222). In some embodiments, the copper floating spreader layer 170 may be formed before or after any of the steps 2110, 2120, and 2130.

Referring to all drawings and according to various embodiments of the present disclosure, a switch is provided, which may include: a heater layer (e.g., 110a, 110b, 110c) including: a first heater pad (e.g., 110a, 110b); a second heater pad (e.g., 110a, 110b); and a heater line (e.g., heating portion 110c) connecting the first heater pad and the second heater pad; a PCM layer 120 positioned in a same vertical plane as the heater line; and a floating spreader layer (e.g., 130, 132, 135, 136, 210, 212, 220, 222) including a first portion (e.g., 210a) positioned in the same vertical plane as the heater line and the PCM layer 120, in which the first portion has a first width (e.g., width W) that is less than or equal to a distance between proximate sidewalls of the first heater pad and the second heater pad.

In some embodiments, the first width may be equal to a width of the PCM layer 120. In some embodiments, the floating spreader layer (e.g., 130, 132, 135, 136, 210, 212, 220, 222) may be a diamond shape with respect to a top-down view, the floating spreader layer may include middle corners (132a, 132b) that are positioned in a same vertical plane as the heater line (e.g., heating portion 110c), and the floating spreader layer may include distal endpoints (131a, 131b) that are equidistant from the middle corners (132a, 132b). In some embodiments, distal ends of the floating spreader layer may be positioned within same vertical planes as distal sidewalls of the PCM layer 120.

In some embodiments, the floating spreader layer may include sidewalls that are parallel to sidewalls of the PCM layer 120. In some embodiments, the switch may further include a whole-area spreader layer (e.g., 135, 136) positioned in the same vertical plane as the floating spreader layer, wherein the floating spreader layer is a copper floating spreader 170 layer in contact with the whole-area spreader layer. In some embodiments, the floating spreader layer may include at least two portions spaced apart from each other.

In some embodiments, the switch may further include a first signal pad (e.g., 150a, 150b) and a second signal pad (e.g., 150a, 150b), in which the floating spreader layer (e.g., 130, 132, 135, 136, 210, 212, 220, 222) extends horizontally outward from vertical planes including sidewalls of the PCM layer 120. In some embodiments, the floating spreader layer may be positioned between vertical planes including proximate sidewalls of the first signal pad and the second signal pad.

In some embodiments, the floating spreader layer (e.g., 130, 132, 135, 136, 210, 212, 220, 222) may include the first portion 210a, and an angled portion 210b that extends outward from the first portion 210a at a tapered angle θ, in which a vertical distance h2 between a periphery of the angled portion 210b and a horizontal plane including a top surface of the PCM layer 120 is greater than a distance between a bottom surface of the first portion 210a and the top surface of the PCM layer 120. In some embodiments, the angled portion 210b may extend beyond a vertical plane including a periphery of the PCM layer 120.

In some embodiments, the floating spreader layer (e.g., 130, 132, 135, 136, 210, 212, 220, 222) may be positioned vertically beneath the heater line (e.g., heating portion 110c). In some embodiments, the floating spreader layer may be positioned vertically above the PCM layer 120. In some embodiments, the switch may further include a second floating spreader layer (e.g., 132, 136, 210, 220, 222) positioned vertically beneath the heater line.

Referring to all drawings and according to various embodiments of the present disclosure, a RF transceiver system for a communication device is provided, which may include an antenna 2005, an RF component section 2015 including a plurality of RF components (e.g., 2015a, 2015b), and a switching module 2010 connected between the antenna 2005 and the RF component section 2015, including a plurality of switches (e.g., 100, 100a, 100b) for switching a signal transmission path between the antenna 2005 and the plurality of RF components 2015. Each switch of the plurality of switches may include a heater layer (e.g., 110a, 110b, 110c) including: a first heater pad (e.g., 110a, 110b); a second heater pad (e.g., 110a, 110b); and a heater line (e.g., heating portion 110c) connecting the first heater pad and the second heater pad; a PCM layer 120 positioned in a same vertical plane as the heater line; and a floating spreader layer (e.g., 130, 132, 135, 136, 210, 212, 220, 222) including a first portion (e.g., 210a) positioned in the same vertical plane as the heater line and the PCM layer 120, in which the first portion has a first width (e.g., width W) that is less than or equal to a distance between proximate sidewalls of the first heater pad and the second heater pad.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A switch, comprising:
a heater layer comprising:
a first heater pad;
a second heater pad; and
a heater line connecting the first heater pad and the second heater pad;
a phase change material (PCM) layer positioned in a same vertical plane as the heater line; and
a floating spreader layer including a first portion positioned in the same vertical plane as the heater line and the PCM layer, wherein the first portion has a first width that is less than or equal to a distance between proximate sidewalls of the first heater pad and the second heater pad.

2. The switch of claim 1, wherein the first width of the first portion is equal to a width of the PCM layer.

3. The switch of claim 1, wherein:
the floating spreader layer is a diamond shape with respect to a top-down view,
the floating spreader layer includes middle corners that are positioned in the same vertical plane as the heater line, and
the floating spreader layer includes distal endpoints that are equidistant from the middle corners.

4. The switch of claim 1, further comprising:
a first signal pad; and
a second signal pad, wherein the floating spreader layer extends horizontally outward from vertical planes including sidewalls of the PCM layer.

5. The switch of claim 1, wherein distal ends of the floating spreader layer are positioned within same vertical planes as distal sidewalls of the PCM layer.

6. The switch of claim 1, further comprising:
a first signal pad; and
a second signal pad, wherein the floating spreader layer is positioned between vertical planes including proximate sidewalls of the first signal pad and the second signal pad.

7. The switch of claim 1, wherein the floating spreader layer includes sidewalls that are parallel to sidewalls of the PCM layer.

8. The switch of claim 1, wherein the floating spreader layer comprises:
the first portion; and
an angled portion that extends outward from the first portion at a tapered angle, wherein a vertical distance between a periphery of the angled portion and a horizontal plane including a top surface of the PCM layer is greater than a distance between a bottom surface of the first portion and the top surface of the PCM layer.

9. The switch of claim 8, wherein the angled portion extends beyond a vertical plane including a periphery of the PCM layer.

10. The switch of claim 1, wherein the floating spreader layer is positioned vertically beneath the heater line.

11. The switch of claim 1, wherein the floating spreader layer is positioned vertically above the PCM layer.

12. The switch of claim 11, further comprising a second floating spreader layer positioned vertically beneath the heater line.

13. The switch of claim 1, further comprising a whole-area spreader layer positioned in the same vertical plane as the floating spreader layer, wherein the floating spreader layer is a copper floating spreader layer in contact with the whole-area spreader layer.

14. The switch of claim 1, wherein the floating spreader layer includes at least two portions spaced apart from each other.

15. A method of forming a switch, comprising:
forming a heater layer including a first heater pad, a second heater pad, and a heater line connecting the first heater pad and the second heater pad;
forming a phase change material (PCM) layer positioned in a same vertical plane as the heater line; and
forming a floating spreader layer including a first portion positioned in the same vertical plane as the heater line and the PCM layer, wherein the floating spreader layer has at least one sidewall overlapping the heater line.

16. The method of claim 15, wherein forming the floating spreader layer positioned in the same vertical plane as the heater line and the PCM layer further comprises:
forming the floating spreader layer in a diamond shape including middle corners and distal endpoints with respect to a top-down view, wherein the middle corners are positioned in a same vertical plane as the heater line, and the distal endpoints are equidistant from the middle corners.

17. The method of claim 15, wherein forming the floating spreader layer positioned in the same vertical plane as the heater line and the PCM layer further comprises:
forming the floating spreader layer to include an angled portion that extends outward from the first portion at a tapered angle, wherein a vertical distance between a periphery of the angled portion and a horizontal plane including a top surface of the PCM layer is greater than a distance between a bottom surface of the first portion and the top surface of the PCM layer.

18. The method of claim 15, wherein forming the floating spreader layer positioned in the same vertical plane as the heater line and the PCM layer further comprises:
forming the floating spreader layer to include at least two portions spaced apart from each other.

19. The method of claim 15, further comprising:
forming a copper floating spreader layer to be in contact with a surface of the floating spreader layer.

20. A radio frequency (RF) transceiver system for a communication device, comprising:
an antenna;
a RF component section including a plurality of RF components; and
a switching module connected between the antenna and the RF component section, including a plurality of switches for switching a signal transmission path between the antenna and the plurality of RF components, each switch of the plurality of switches comprising:
a heater layer comprising:
a first heater pad;
a second heater pad; and
a heater line connecting the first heater pad and the second heater pad;
a phase change material (PCM) layer positioned in a same vertical plane as the heater line; and
a floating spreader layer including a first portion positioned in the same vertical plane as the heater line and the PCM layer, wherein the first portion has a first width that is less than or equal to a distance between proximate sidewalls of the first heater pad and the second heater pad.
